(19) United States
(12) Patent Application Publication
(10) Pub. No.: US 2025/0355066 A1
(43) Pub. Date: Nov. 20, 2025

(54) MAGNETORESISTIVE DEVICE AND METHOD FOR MANUFACTURING THE SAME, AND MAGNETIC SENSOR

(71) Applicant: TDK Corporation, Tokyo (JP)

(72) Inventors: Norikazu OTA, Tokyo (JP); Yoshitaka SASAKI, Uniondale, NY (US)

(73) Assignee: TDK Corporation, Tokyo (JP)

(21) Appl. No.: 18/664,446

(22) Filed: May 15, 2024

(51) Int. Cl. G01R 33/09; G01R 33/00

(52) U.S. Cl. CPC G01R 33/093; G01R 33/0052

(57) ABSTRACT

A magnetoresistive device includes at least one magnetoresistive element and at least one electrode including at least one connection portion connected to the at least one magnetoresistive element. The at least one magnetoresistive element includes a magnetization pinned layer, a free layer configured to have a magnetic vortex structure and configured so that a center of the magnetic vortex structure moves depending on a target magnetic field, and a gap layer. The magnetization pinned layer, the free layer, and the gap layer are stacked in a certain stacking direction. The at least one connection portion has a contact surface being in contact with the at least one magnetoresistive element and having an identical shape to that of the free layer when seen in the stacking direction, and a circumferential surface connected to the contact surface and having a certain dimension in the stacking direction.

### BACKGROUND

The technology relates to a magnetoresistive device including a magnetoresistive element using a free layer having a magnetic vortex structure and a method for manufacturing the same, and a magnetic sensor including this magnetoresistive device.

In recent years, magnetic sensors using magnetic detection effective elements are used for various purposes. As such a magnetic detection effective element, a spin-valve type magnetoresistive element is used, for example. The spin-valve type magnetoresistive element includes a magnetization pinned layer having a magnetization whose direction is fixed, a free layer having a magnetization whose direction is variable depending on a magnetic field to be applied, and a gap layer disposed between the magnetization pinned layer and the free layer.

As such a spin-valve type magnetoresistive element, a current perpendicular to plane (CPP) type magnetoresistive element where a current for use in magnetic signal detection is fed in a direction substantially perpendicular to the plane of each layer constituting the magnetoresistive element is known. In the CPP type magnetoresistive element, a magnetoresistive element is disposed between a lower electrode and an upper electrode. The upper electrode is connected to the magnetoresistive element via a contact hole provided in an insulating layer covering the magnetoresistive element.

As an angular sensor using such spin-valve type magnetoresistive elements, known is an angular sensor that include two detection circuits each including a bridge circuit using magnetoresistive elements, the two detection circuits being different from each other in phase of output characteristics, as disclosed in US 2021/0405132 A1. US 2021/0405132 A1 also discloses a magnetic field strength sensor using magnetoresistive elements each including a free layer having a magnetic vortex structure (also referred to as a vortex structure), in addition to the angular sensor. The angular sensor and the magnetic field strength sensor are provided on the same substrate to form one magnetic sensor.

When a comparison is made with the magnetic sensor being the same in size, it is desired, in order to reduce noise components included in a detection signal of the magnetic sensor, to reduce the resistance of the entire magnetic sensor and also increase the number of magnetoresistive elements per unit area. However, it has been difficult to increase the number of magnetoresistive elements in a magnetic sensor using CPP type magnetoresistive elements. Specifically, to reduce the resistance of the entire magnetic sensor, it is necessary to enlarge contact holes in the insulating layer to increase the contact area of the magnetoresistive elements and the upper electrodes. However, from the viewpoint of alignment precision of photoresist masks used in the manufacturing of the magnetic sensor and the like, the plane shapes of the magnetoresistive elements need to be made larger than the plane shapes of the contact holes to some extent. For these reasons, it has been difficult heretofore to increase the number of magnetoresistive elements per unit area.

To securely connect the upper electrodes to the magnetoresistive elements, it has been necessary to make the plane shapes of the upper electrodes larger than the plane shapes of the contact holes, to completely fill the contact holes. For this reason, it has been difficult heretofore to reduce the distance between two adjacent upper electrodes and consequently difficult to reduce the distance between two magnetoresistive elements. Also for this reason, it has been difficult to increase the number of magnetoresistive elements per unit area.

### SUMMARY

A magnetoresistive device according to one embodiment of the technology includes: at least one magnetoresistive element including a magnetization pinned layer having a magnetization whose direction is fixed, a free layer configured to have a magnetic vortex structure and configured so that a center of the magnetic vortex structure moves depending on a target magnetic field, and a gap layer disposed between the magnetization pinned layer and the free layer, the magnetization pinned layer, the free layer, and the gap layer being stacked together in a certain stacking direction; and at least one electrode including at least one connection portion connected to the at least one magnetoresistive element. The at least one connection portion has a contact surface being in contact with the at least one magnetoresistive element and having an identical shape to a shape of the free layer when seen in the stacking direction, and a circumferential surface connected to the contact surface and having a certain dimension in the stacking direction.

A method for manufacturing a magnetoresistive device according to one embodiment of the technology includes: a step of forming a layered film to later be the at least one magnetoresistive element; a step of forming a hard mask on the layered film; a step of etching, by using the hard mask, the layered film to be the at least one magnetoresistive element; a step of forming an insulating layer around the at least one magnetoresistive element; a step of removing the hard mask; and a step of forming the at least one electrode.

A magnetic sensor according to one embodiment of the technology includes the magnetoresistive device according to one embodiment of the technology and is configured to detect a target magnetic field and generate a detection signal. The detection signal has a correspondence with a resistance of at least one magnetoresistive element.

In the magnetoresistive device and the magnetic sensor according to one embodiment of the technology, the at least one connection portion has a contact surface being in contact with the at least one magnetoresistive element and having an identical shape to that of the free layer when seen in the stacking direction, and a circumferential surface connected to the contact surface and having a certain dimension in the stacking direction. In view of these, according to one embodiment of the technology, the number of magnetoresistive elements per unit area can be increased.

Other and further objects, features, and advantages of the technology will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a part of a magnetoresistive device according to a first example embodiment of the technology.

FIG. 2 is a cross-sectional view showing a part of the magnetoresistive device according to the first example embodiment of the technology.

FIG. 3 is a plan view showing a part of the magnetoresistive device according to the first example embodiment of the technology.

FIG. 4 is a perspective view showing magnetoresistive elements, connection portions, and a lower electrode in the first example embodiment of the technology.

FIG. 5 is a perspective view showing a magnetoresistive element in the first example embodiment of the technology.

FIG. 6 is a plan view showing a free layer of the magnetoresistive element in the first example embodiment of the technology.

FIG. 7 is a plan view showing the free layer when a target magnetic field is applied to the magnetoresistive element in the first example embodiment of the technology.

FIG. 8 is a plan view showing the free layer when a target magnetic field is applied to the magnetoresistive element in the first example embodiment of the technology.

FIG. 9 is a circuit diagram showing a circuit configuration of a magnetic sensor according to the first example embodiment of the technology.

FIG. 10 is a cross-sectional view showing a step of a method for manufacturing the magnetoresistive device according to the first example embodiment of the technology.

FIG. 11 is a cross-sectional view showing a step subsequent to the step shown in FIG. 10.

FIG. 12 is a cross-sectional view showing a step subsequent to the step shown in FIG. 11.

FIG. 13 is a perspective view showing magnetoresistive elements and hard masks shown in FIG. 12.

FIG. 14 is a cross-sectional view showing a step subsequent to the step shown in FIG. 12.

FIG. 15 is a cross-sectional view showing a step subsequent to the step shown in FIG. 14.

FIG. 16 is a cross-sectional view showing a step subsequent to the step shown in FIG. 15.

FIG. 17 is a cross-sectional view showing a step subsequent to the step shown in FIG. 16.

FIG. 18 is a cross-sectional view showing a step subsequent to the step shown in FIG. 17.

FIG. 19 is a cross-sectional view showing a step subsequent to the step shown in FIG. 18.

FIG. 20 is a perspective view showing a first modification example of the magnetoresistive elements in the first example embodiment of the technology.

FIG. 21 is a perspective view showing a second modification example of the magnetoresistive elements in the first example embodiment of the technology.

FIG. 23 is a perspective view showing a modification example of upper electrodes in the first example embodiment of the technology.

FIG. 23 is a cross-sectional view showing a part of a magnetoresistive device according to a second example embodiment of the technology.

FIG. 24 is a cross-sectional view showing a step of a method for manufacturing the magnetoresistive device according to the second example embodiment of the technology.

FIG. 25 is a cross-sectional view showing a step subsequent to the step shown in FIG. 24.

FIG. 26 is a cross-sectional view showing a step subsequent to the step shown in FIG. 25.

FIG. 27 is a cross-sectional view showing a step subsequent to the step shown in FIG. 26.

FIG. 28 is a cross-sectional view showing a step subsequent to the step shown in FIG. 27.

FIG. 29 is a cross-sectional view showing a step subsequent to the step shown in FIG. 28.

FIG. 30 is a cross-sectional view showing a step of a method for manufacturing a magnetoresistive device according to a third example embodiment of the technology.

FIG. 31 is a cross-sectional view showing a step subsequent to the step shown in FIG. 30.

FIG. 32 is a cross-sectional view showing a step subsequent to the step shown in FIG. 31.

FIG. 33 is a cross-sectional view showing a step subsequent to the step shown in FIG. 32.

FIG. 34 is a cross-sectional view showing a step subsequent to the step shown in FIG. 33.

FIG. 35 is a cross-sectional view showing a step subsequent to the step shown in FIG. 34.

FIG. 36 is a cross-sectional view showing a step subsequent to the step shown in FIG. 35.

FIG. 37 is a cross-sectional view showing a step subsequent to the step shown in FIG. 36.

FIG. 38 is a perspective view showing a part of a magnetoresistive device according to a fourth example embodiment of the technology.

FIG. 39 is a perspective view showing a part of a magnetoresistive device according to a fifth example embodiment of the technology.

FIG. 40 is a perspective view showing a part of a modification example of the magnetoresistive device according to the fifth example embodiment of the technology.

FIG. 41 is a circuit diagram showing a circuit configuration of a magnetic sensor according to a sixth example embodiment of the technology.

FIG. 42 is a perspective view showing a part of a magnetic sensor according to the sixth example embodiment of the technology.

FIG. 43 is a plan view showing a part of the magnetic sensor according to the sixth example embodiment of the technology.

FIG. 44 is a side view showing a part of the magnetic sensor according to the sixth example embodiment of the technology.

FIG. 45 is a circuit diagram showing a circuit configuration of a first detection circuit of a magnetic sensor according to a seventh example embodiment of the technology.

FIG. 46 is a circuit diagram showing a circuit configuration of a second detection circuit of the magnetic sensor according to the seventh example embodiment of the technology.

FIG. 47 is a plan view showing a part of the magnetic sensor according to the seventh example embodiment of the technology.

FIG. 48 is a cross-sectional view showing a part of the magnetic sensor according to the seventh example embodiment of the technology.

### DETAILED DESCRIPTION

An object of the technology is to provide a magnetoresistive device possible to have an increased number of magnetoresistive elements per unit area, a method of manufacturing the same, and a magnetic sensor including this magnetoresistive device.

In the following, some example embodiments and modification examples of the technology will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. Note that the description is given in the following order.

### First Example Embodiment

A configuration of a magnetoresistive device according to a first example embodiment of the technology will initially be described briefly. A magnetoresistive device 10 according to the example embodiment includes at least one magnetoresistive element whose resistance changes depending on a target magnetic field, which is a detection-target magnetic field, and a plurality of electrodes connected to the at least one magnetoresistive element. The magnetoresistive element is referred to as an MR element below.

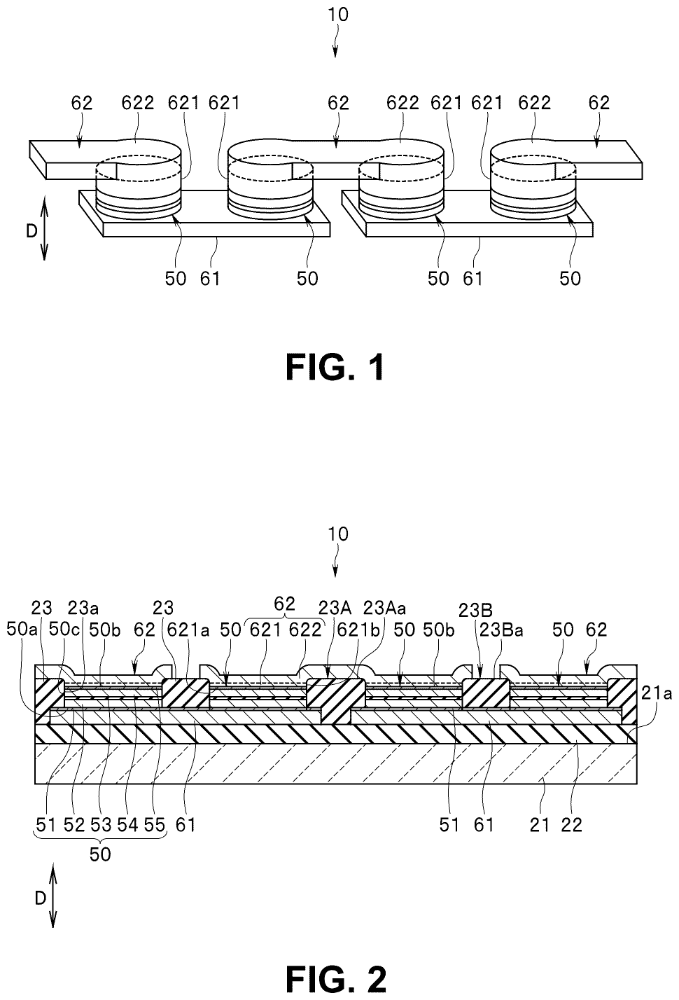

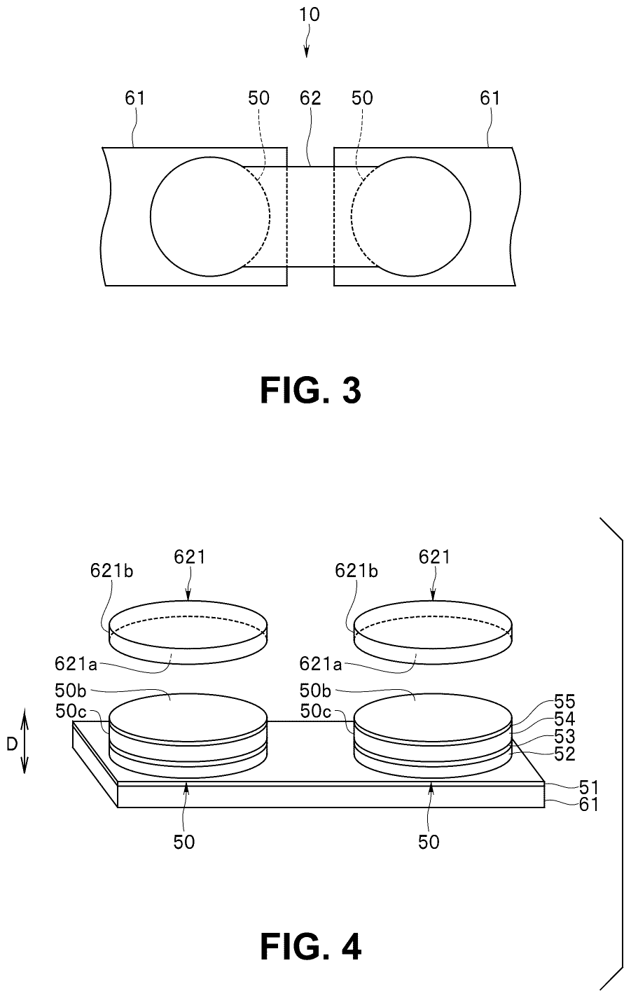

The configuration of the magnetoresistive device 10 will now be described in detail with reference to FIG. 1 to FIG. 4. FIG. 1 is a perspective view showing a part of the magnetoresistive device 10. FIG. 2 is a cross-sectional view showing a part of the magnetoresistive device 10. FIG. 3 is a plan view showing a part of the magnetoresistive device 10. FIG. 4 is a perspective view showing MR elements, connection portions, and a lower electrode.

The magnetoresistive device 10 includes a plurality of MR elements 50 as the at least one MR element. Each of the plurality of MR elements 50 has a bottom surface 50a, a top surface 50b opposite to the bottom surface 50a, and a side surface 50c connecting the bottom surface 50a and the top surface 50b. In the example embodiment, in particular, each of the plurality of MR elements 50 has a cylindrical or substantially cylindrical shape. Each of the bottom surface 50a and the top surface 50b has a cylindrical or substantially cylindrical shape.

As will be described below, the MR element 50 is formed by stacking a plurality of layers together. In FIG. 1, FIG. 2, and FIG. 4, arrows with a reference sign D indicate a stacking direction of the plurality of layers. The bottom surface 50a and the top surface 50b are located at respective both ends of the MR element 50 in a stacking direction D.

The magnetoresistive device 10 includes a plurality of upper electrodes 62 and a plurality of lower electrodes 61 as the plurality of electrodes. The plurality of lower electrodes 61 and the plurality of upper electrodes 62 are formed of Au, Cu, or Ta, for example.

Each lower electrode 61 has a long slender shape. There is a gap formed between two lower electrodes 61 adjacent in the longitudinal direction of the lower electrodes 61. The MR elements 50 are disposed on the top surface of each lower electrode 61, near both ends in the longitudinal direction. Each upper electrode 62 has a long slender shape and electrically connects two adjacent MR elements 50 disposed on two lower electrodes 61 adjacent in the longitudinal direction of the lower electrodes 61.

Each upper electrode 62 includes two connection portions 621 and a joining portion 622 joining the two connection portions 621. In FIG. 1 and FIG. 2, boundaries between the two connection portions 621 and the joining portion 622 are illustrated with dotted lines. Each of the two connection portions 621 is connected to the top surface 50b of a corresponding one of the MR elements 50. In FIG. 4, the two connection portions 621 are illustrated to be spaced from the MR elements 50 for convenience.

Each connection portion 621 has a contact surface 621a being in contact with the MR element 50 and a circumferential surface 621b connected to the contact surface 621a. The circumferential surface 621b has a first end connected to the contact surface 621a and a second end connected to the joining portion 622. No other portion than the upper electrode 62 is connected to the portion of the circumferential surface 621b excluding the first end and the second end. The circumferential surface 621b has a certain dimension in the stacking direction D. The connection portion 621 has a cylindrical or substantially cylindrical shape.

The angle of the circumferential surface 621b with respect to the stacking direction D is within a range of 0° to 7°, for example. In a section intersecting the connection portion 621 and being parallel to the stacking direction D, a distance between one end portion and the other end portion of the circumferential surface 621b may be constant irrespective of the distance from the contact surface 621a, may be increased as being away from the contact surface 621a, or may be reduced as being away from the contact surface 621a. In the example embodiment, in particular, the connection portion 621 has a cylindrical or substantially cylindrical shape. The diameter of the circumferential surface 621b may be constant irrespective of the distance from the contact surface 621a, may be increased as being away from the contact surface 621a, or may be reduced as being away from the contact surface 621a.

Now, a relationship between the two connection portions 621 included in one upper electrode 62 will be described. In a section intersecting the two connection portions 621 and being parallel to the stacking direction D, the circumferential surface 621b of one of the two connection portions 621 and the circumferential surface 621b of the other one of the two connection portions 621 are substantially parallel to each other. Note that a case of being substantially parallel includes a case of being regarded as, although being not completely parallel, being parallel from the viewpoint of precision in manufacturing of the magnetoresistive device 10, in addition to a case of being completely parallel.

The distance between the circumferential surface 621b of the one of the two connection portion 621 and the circumferential surface 621b of the other one of the two connection portions 621 is substantially constant irrespective of the position in the stacking direction D. Note that a case where the distance is substantially constant includes a case where the distance is regarded as, although being not completely constant, being constant from the viewpoint of precision in manufacturing of the magnetoresistive device 10, in addition to a case where the distance is completely constant.

The above description of the relationship between the two connection portions 621 included in one upper electrode 62 also applies to the two connection portions 621 included in two respective adjacent upper electrodes 62.

The joining portion 622 connects the end portions, which are opposite to the contact surfaces 621a, of the two connection portions 621 to each other. When seen in the stacking direction D, a part of an outer edge of the joining portion 622 may coincide, but need not coincide, with a part of an outer edge of each connection portion 621. Note that, in FIG. 1, the peripheral edges of the joining portion 622 and the peripheral edges of the connection portions 621 are illustrated to coincide with each other, at both ends of the joining portion 622 in the longitudinal direction when seen in the stacking direction D, for convenience. However, the peripheral edges of the joining portion 622 need not coincide with the peripheral edges of the connection portions 621 at both ends of the joining portion 622 in the longitudinal direction when seen in the stacking direction D as illustrated in FIG. 2.

The magnetoresistive device 10 further includes a substrate 21 having a top surface 21a, and insulating layers 22 and 23. The insulating layer 22 is disposed on the top surface 21a of the substrate 21. The lower electrodes 61 are disposed on the insulating layer 22. The MR elements 50 are disposed on the lower electrodes 61. The connection portions 621 are disposed on the MR elements 50. The insulating layer 23 is disposed around the MR elements 50, the lower electrodes 61, and the connection portions 621. The joining portion 622 is disposed on the connection portions 621 and the insulating layer 23. The insulating layers 22 and 23 are formed of SiO₂ or Al₂O₃, for example.

The insulating layer 23 has a facing surface 23a facing the side surface 50c of each MR element 50 and the circumferential surface 621b of a corresponding one of the connection portions 621. The angle of at least a part of the facing surface 23a with respect to the stacking direction D is within a range of 0° to 7°, for example.

The insulating layer 23 includes a first portion 23A and a second portion 23B that are arranged to sandwich one MR element 50 and one connection portion 621 connected to this one MR element 50. The first portion 23A is one end in the stacking direction D and has an end portion 23Aa located at one end furthest from the substrate 21. The second portion 23B is one end in the stacking direction D and has an end portion 23Ba located at one end furthest from the substrate 21. The end portion 23Aa and the end portion 23Ba are at substantially the same position in the stacking direction D. Note that a case of being at substantially the same position includes a case of being regarded as, although being not at completely the same position, being at the same position from the viewpoint of precision in manufacturing of the magnetoresistive device 10, in addition to a case of being at completely the same position.

The end portion 23Aa of the first portion 23A and the end portion 23Ba of the second portion 23B are disposed at a position further from the top surface 21a of the substrate 21 than the top surface 50b of the MR element 50 is. In other words, the distance between the end portion 23Aa of the first portion 23A and the top surface 21a of the substrate 21 and the distance between the end portion 23Ba of the second portion 23B and the top surface 21a of the substrate 21 are larger than the distance between the top surface 50b of the MR element 50 and the top surface 21a of the substrate 21. The insulating layer 23 is not in contact with the top surface 50b of the MR element 50.

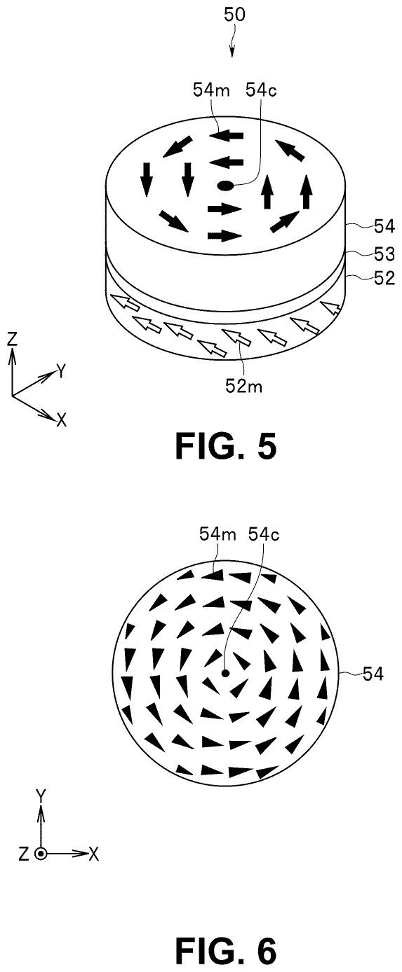

Next, a configuration of each MR element 50 will be described in detail with reference to FIG. 2, FIG. 4, FIG. 5, and FIG. 6. FIG. 5 is a perspective view showing the MR element 50. FIG. 6 is a plan view showing a free layer of the MR element 50.

Here, an X direction, a Y direction, and a Z direction will be defined as shown in FIG. 5 and FIG. 6. The X direction, the Y direction, and the Z direction are orthogonal to each other. The opposite directions to the X direction, the Y direction, and the Z direction are defined as −X, −Y, and −Z directions, respectively.

“Above” hereinafter refers to positions located forward of a reference position in the Z direction, and “below” refers to positions opposite from the “above” positions with respect to the reference position. Regarding components of the magnetoresistive device 10, the “top surface” refers to a surface located at a Z-direction end, and “bottom surface” refers to a surface located at a −Z-direction end. The expression “when seen in a certain direction (for example, the Z direction)” means to see an object from a position away in the certain direction or one direction parallel to the certain direction.

The stacking direction D shown in FIG. 1, FIG. 2, and FIG. 4 is parallel to the Z direction. In the example embodiment, the direction from the lower electrode 61 to the upper electrode 62 in the stacking direction D is defined as the Z direction.

The MR element 50 includes a magnetization pinned layer 52 having a magnetization 52m whose direction is fixed, a free layer 54, and a gap layer 53 located between the magnetization pinned layer 52 and the free layer 54. The material and shape of the free layer 54 are selected so that the free layer 54 has a magnetic vortex structure (also referred to as a vortex structure) under a circumstance where magnetization is not saturated. The gap layer 53 is a tunnel barrier layer or a nonmagnetic conductive layer.

The free layer 54 has a cylindrical or substantially cylindrical shape. The free layer 54 has a magnetization 54m that is vortical about a center 54c of the magnetic vortex structure. When there is no magnetic field applied to the MR element 50, the center 54c of the magnetic vortex structure coincides or substantially coincides with the axis of the cylinder. The center 54c of the magnetic vortex structure moves depending on the target magnetic field.

The center 54c of the magnetic vortex structure moves if a component of the target magnetic field in a direction orthogonal to the Z direction is applied to the free layer 54. When the above component of the target magnetic field increases in strength, and the magnetization of the free layer 54 reaches saturation, the magnetic vortex structure of the free layer 54 is lost. For this reason, it is preferable that the magnetization of the free layer 54 is not saturated within the range of variations in the strength of the above component of the target magnetic field.

Note that, when the magnetic vortex structure of the free layer 54 is lost and the strength of the above component of the target magnetic field falls below a certain strength, the magnetic vortex structure of the free layer 54 is re-formed.

The magnetization 52m of the magnetization pinned layer 52 may include a component in a direction parallel to the X direction or may include a component in a direction parallel to the Z direction. FIG. 5 shows an example of a case where the magnetization 52m of the magnetization pinned layer 52 includes a component in the direction parallel to the X direction. Note that, if the magnetization 52m of the magnetization pinned layer 52 includes a component in a specific direction, the component in the specific direction may be the main component of the magnetization 52m of the magnetization pinned layer 52. Alternatively, the magnetization 52m of the magnetization pinned layer 52 may be free of a component in a direction orthogonal to the specific direction. In the example embodiment, if the magnetization 52m of the magnetization pinned layer 52 includes a component in the specific direction, the direction of the magnetization 52m of the magnetization pinned layer 52 is the same or substantially the same as the specific direction.

The MR element 50 may further include an antiferromagnetic layer. The antiferromagnetic layer is formed of an antiferromagnetic material and is in exchange coupling with the magnetization pinned layer 52 to thereby pin the direction of the magnetization of the magnetization pinned layer 52. Alternatively, the magnetization pinned layer 52 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled.

The MR element 50 further includes a buffer layer 51 and a cap layer 55. The buffer layer 51, the magnetization pinned layer 52, the gap layer 53, the free layer 54, and the cap layer 55 are stacked in this order in the Z direction. Note that the buffer layer 51 and the cap layer 55 are shown in FIG. 2 and FIG. 4. In the examples shown in FIG. 2 and FIG. 4, the buffer layer 51 is used by the two MR elements 50 in common. The buffer layer 51 may be formed on the entire top surface of the lower electrode 61. Each of the buffer layer 51 and the cap layer 55 is formed of a non-magnetic metallic material such as Ru, Ta, Cu, or Cr, for example.

Note that the shape of the buffer layer 51 is not limited to the example shown in FIG. 2 and FIG. 4. For example, the plane shape (shape when seen in the stacking direction D) of the buffer layer 51 may be the same as the plane shape of the magnetization pinned layer 52.

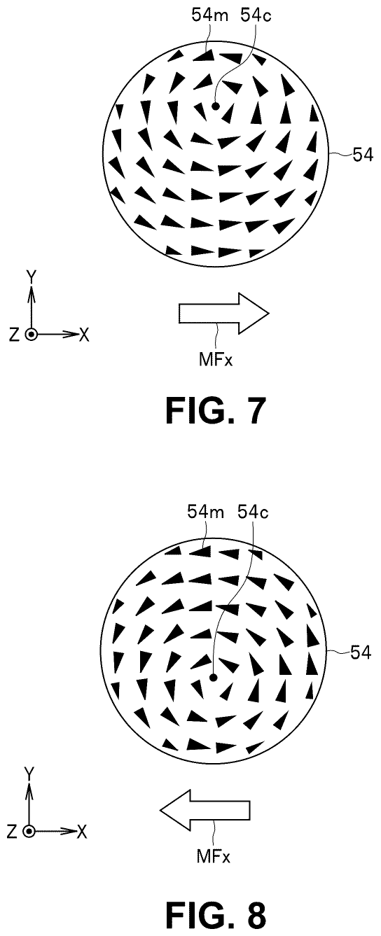

The resistance of the MR element 50 will now be described by using an example case where the direction of the magnetization 52m of the magnetization pinned layer 52 is the −X direction. FIG. 7 and FIG. 8 show the free layer 54 when a magnetic field component MFx of the target magnetic field in a direction parallel to the X direction is applied to the free layer 54.

FIG. 7 shows the free layer 54 when the direction of the magnetic field component MFx is the X direction. In this case, the center 54c of the magnetic vortex structure moves due to the magnetic field component MFx, and also the amount of the magnetization 54m in the X direction is larger than the amount of magnetization 54m in the −X direction. In this case, the resistance of the MR element 50 increases.

FIG. 8 shows the free layer 54 when the direction of the magnetic field component MFx is the −X direction. In this case, the center 54c of the magnetic vortex structure moves due to the magnetic field component MFx, and the amount of the magnetization 54m in the −X direction is larger than the amount of the magnetization 54m in the X direction. In this case, the resistance of the MR element 50 decreases.

The amount of change in the resistance of the MR element 50 depends on the strength of the magnetic field component MFx. When the direction of the magnetic field component MFx is the X direction, and the strength of the magnetic field component MFx increases, the amount of the magnetization 54m in the X direction increases. The resistance of the MR element 50 increases as the amount of the magnetization 54m in the X direction increases. When the direction of the magnetic field component MFx is the −X direction, and the strength of the magnetic field component MFx increases, the amount of the magnetization 54m in the −X direction increases. The resistance of the MR element 50 decreases as the amount of the magnetization 54m in the −X direction decreases. As the strength of the magnetic field component MFx increases, the resistance of the MR element 50 changes so that the amount of increase or the amount of decrease increases. As the strength of the magnetic field component MFx decreases, the resistance of the MR element 50 changes so that the amount of increase or the amount of decrease decreases.

Now, structural features related to the MR element 50 and the upper electrode 62 will be described. The contact surface 621a of the connection portion 621 of the upper electrode 62 has a shape identical to that of the free layer 54 of the MR element 50 when seen in the stacking direction D. The outer edge of the contact surface 621a may coincide with or may substantially coincide with the outer edge of the top surface 50b of the MR element 50.

The contact surface 621a of the connection portion 621 of the upper electrode 62 may have an identical shape to that of the magnetization pinned layer 52 of the MR element 50 when seen in the stacking direction D. The MR element 50 may include a portion having a shape larger than the connection portion 621 of the upper electrode 62 when seen in the stacking direction D. In the example embodiment, the MR element 50 includes the buffer layer 51 as the above portion.

Next, a configuration of a magnetic sensor 1 according to the example embodiment will be described. The magnetic sensor 1 includes the magnetoresistive device 10 and is configured to detect a target magnetic field and generate a detection signal. The detection signal has a correspondence with the resistances of the plurality of MR elements 50 of the magnetoresistive device 10.

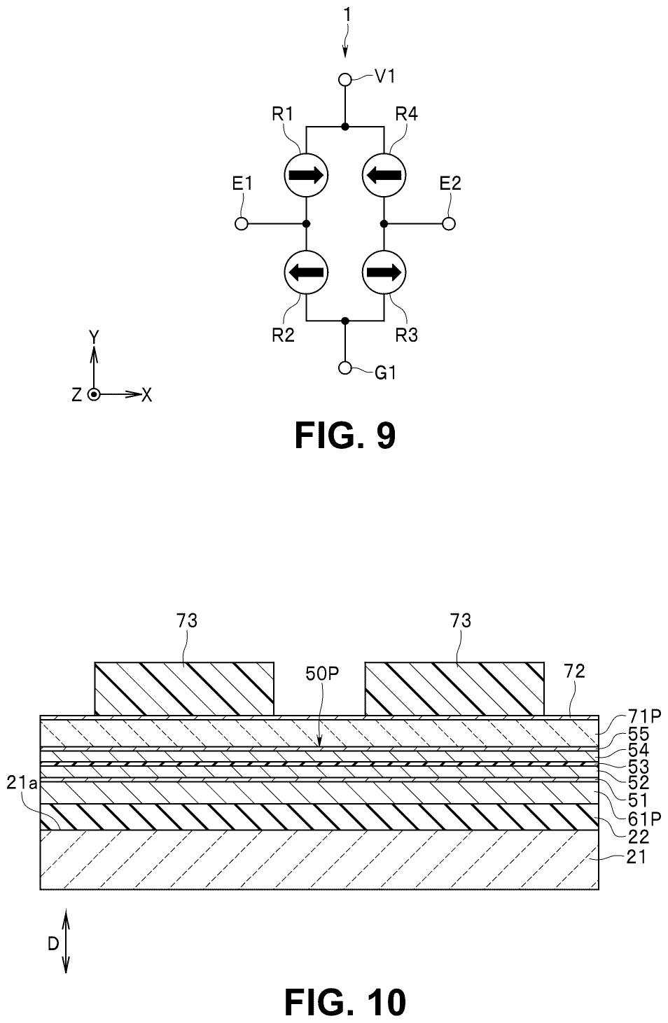

The configuration of the magnetic sensor 1 will be described below in detail with reference to FIG. 9. FIG. 9 is a circuit diagram showing a circuit configuration of the magnetic sensor 1. The magnetic sensor 1 includes four resistance portions R1, R2, R3, and R4, a power supply port V1, a ground port G1, and two output ports E1 and E2. The resistance portion R1 is provided between the power supply port V1 and the output port E1. The resistance portion R2 is provided between the output port E1 and the ground port G1. The resistance portion R3 is provided between the output port E2 and the ground port G1. The resistance portion R4 is provided between the power supply port V1 and the output port E2. A voltage or current of predetermined magnitude is applied to the power supply port V1. The ground port G1 is grounded.

Each of the resistance portions R1 to R4 is constituted by using the magnetoresistive device 10. In each of the resistance portions R1 to R4, the plurality of MR elements 50 of the magnetoresistive device 10 are connected in series.

In FIG. 9, an arrow illustrated to overlap each of the resistance portions R1 to R4 indicates the direction of the magnetization 52m of the magnetization pinned layer 52 of each MR element 50 in each of the resistance portions R1 to R4. In the example shown in FIG. 9, the direction of the magnetization 52m of the magnetization pinned layer 52 of each MR element 50 in each of the resistance portions R1 and R3 is the X direction. The direction of the magnetization 52m of the magnetization pinned layer 52 of each MR element 50 in each of the resistance portions R2 and R4 is the −X direction.

The amount of change in the resistance of each of the resistance portions R1 to R4 depends on the strength of the magnetic field component MFx that each of the plurality of MR elements 50 receives (refer to FIG. 7 and FIG. 8). As the strength of the magnetic field component MFx increases, the resistance of each of the resistance portions R1 to R4 changes so that the amount of increase or the amount of decrease increases. As the strength of the magnetic field component MFx decreases, the resistance of each of the resistance portions R1 to R4 changes so that the amount of increase or the amount of decrease decreases.

In the magnetic sensor 1, when the direction and strength of the magnetic field component MFx change, the resistance of each of the resistance portions R1 to R4 changes so that the resistance of each of the resistance portions R1 and R3 increases and the resistance of each of the resistance portions R2 and R4 decreases, or so that the resistance of each of the resistance portions R1 and R3 decreases and the resistance of each of the resistance portions R2 and R4 increases. Consequently, the potential at the connection point of the resistance portions R1 and R2, i.e., the potential at the output port E1, and the potential at the connection point of the resistance portions R3 and R4, i.e., the potential at the output port E2, change. The magnetic sensor 1 may generate a signal corresponding to the potential at the output port E1 and a signal corresponding to the potential at the output port E2, as detection signals. Alternatively, the magnetic sensor 1 may generate a signal corresponding to a potential difference between the output ports E1 and E2, as a detection signal. In this case, the magnetic sensor 1 may further include a differential amplifier (differential detector) that outputs a signal corresponding to a potential difference between the output ports E1 and E2, as a detection signal. A detection signal generated by the magnetic sensor 1 has a correspondence with the direction and strength of the magnetic field component MFx.

Note that the configuration of the magnetic sensor 1 according to the example embodiment is not limited to the example shown in FIG. 9. For example, the direction of the magnetization 52m of the magnetization pinned layer 52 of each MR element 50 in each of the resistance portions R1 and R3 may be defined as the Y direction, and the direction of the magnetization 52m of the magnetization pinned layer 52 of each MR element 50 in each of the resistance portions R2 and R4 may be defined as the −Y direction. In this case, in the magnetic sensor 1, when the direction and strength of a magnetic field component MFy in a direction parallel to the Y direction of the target magnetic field change, the resistance of each of the resistance portions R1 to R4 changes so that the resistance of each of the resistance portions R1 and R3 increases and the resistance of each of the resistance portions R2 and R4 decreases, or so that the resistance of each of the resistance portions R1 and R3 decreases and the resistance of each of the resistance portions R2 and R4 increases. A detection signal generated by the magnetic sensor 1 has a correspondence with the direction and strength of the magnetic field component MFy.

Next, a method for manufacturing the magnetoresistive device 10 according to the example embodiment will be described with reference to FIG. 10 to FIG. 19. FIG. 10 to FIG. 19 show cross-sectional views in a process of manufacturing the magnetoresistive device 10.

In the method for manufacturing the magnetoresistive device 10, first, the insulating layer 22 is formed on the substrate 21 as shown in FIG. 10. Then, on the insulating layer 22, a metal layer 61P to later become the plurality of lower electrodes 61 is formed. Then, on the metal layer 61P, a layered film 50P to later become the plurality of MR elements 50 is formed. The layered film 50P includes the buffer layer 51, the magnetization pinned layer 52, the gap layer 53, the free layer 54, and the cap layer 55.

Then, on the layered film 50P, a hard mask material layer 71P is formed. In the example embodiment, in particular, the hard mask material layer 71P is formed of carbon. Then, on the hard mask material layer 71P, a non-magnetic metal layer 72 formed of Ta, for example, is formed. Then, on the non-magnetic metal layer 72, a plurality of photoresist masks 73 are formed. The plurality of photoresist masks 73 have a plane shape corresponding to the MR elements 50.

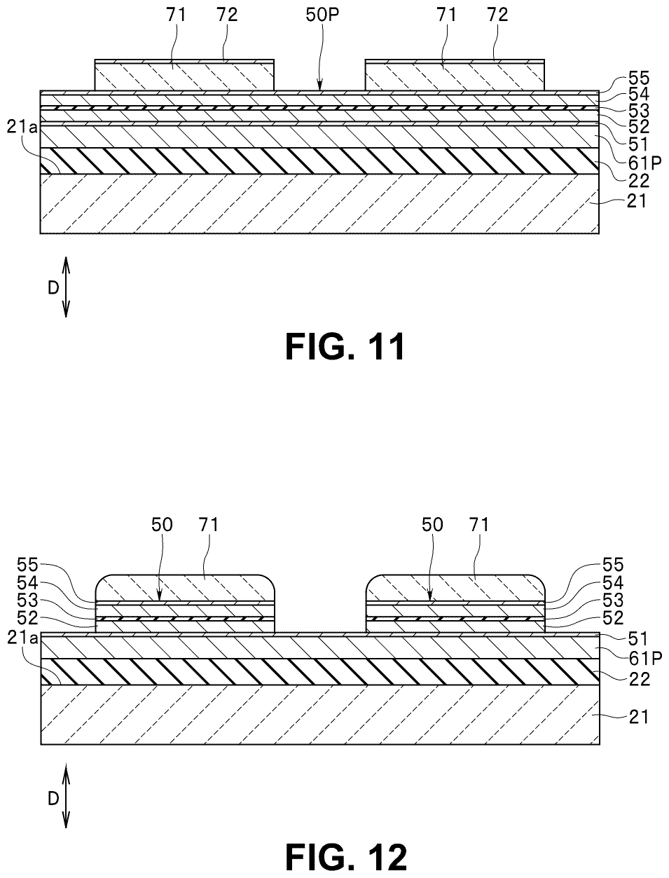

FIG. 11 shows the next step. In this step, first, by using the plurality of photoresist masks 73 as etching masks, the non-magnetic metal layer 72 is etched by reactive ion etching (referred to as RIE below) or ion beam etching (referred to as IBE below). Then, by using the non-magnetic metal layer 72 and the plurality of photoresist masks 73 as etching masks, the hard mask material layer 71P is etched so that the hard mask material layer 71P becomes a plurality of hard masks 71. When the hard mask material layer 71P is formed of carbon, the hard mask material layer 71P may be etched by plasma etching using etching gas containing O₂, for example. Then, the plurality of photoresist masks 73 are removed.

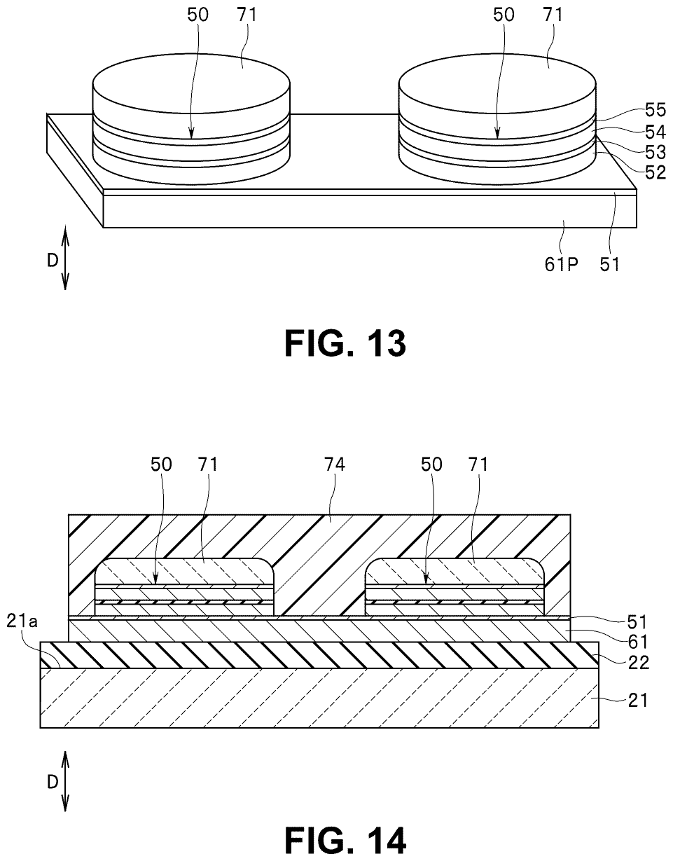

FIG. 12 and FIG. 13 show the next step. In this step, by using the plurality of hard masks 71 as etching masks, the layered film 50P is etched by IBE, for example, so that the layered film 50P becomes the plurality of MR elements 50. This etching may be performed until the buffer layer 51 is exposed, for example. In this etching, the non-magnetic metal layer 72 is also etched.

In the step of etching the layered film 50P, substances scattered due to the etching form a re-deposited film in some cases. When the layered film 50P is etched by IBE, the traveling direction of ion beams is inclined relative to a direction perpendicular to the top surface 21a of the substrate 21 to (stacking direction D) successfully remove the re-deposited film.

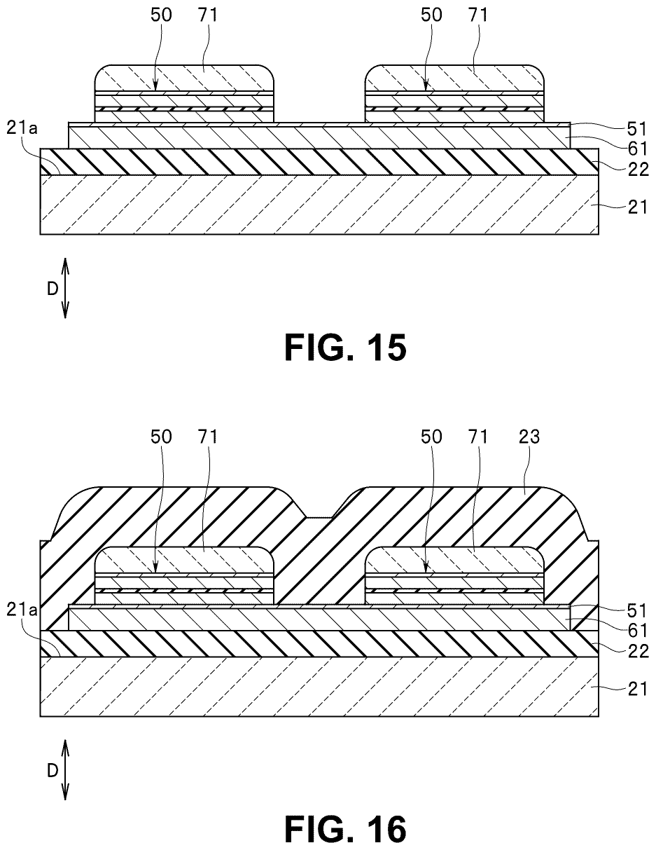

FIG. 14 shows the next step. In this step, first, a plurality of photoresist masks 74 are formed to cover the plurality of MR elements 50 and the plurality of hard masks 71. The plurality of photoresist masks 74 have a plane shape corresponding to the lower electrodes 61. Then, by using the plurality of photoresist masks 74 as etching masks, the metal layer 61P is etched by RIE or IBE, for example, so that the metal layer 61P becomes the plurality of lower electrodes 61. Then, as shown in FIG. 15, the plurality of photoresist masks 74 are removed.

FIG. 16 shows the next step. In this step, the insulating layer 23 is formed on the entire top surface of a stack. The insulating layer 23 is also formed around the plurality of MR elements 50 and the plurality of lower electrodes 61.

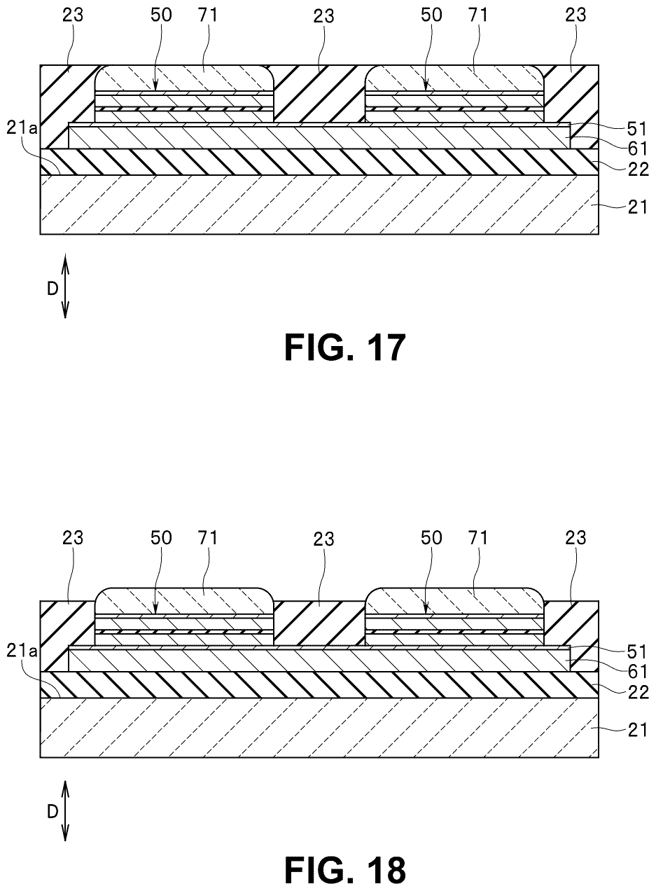

FIG. 17 shows the next step. In this step, the insulating layer 23 is polished by chemical mechanical polishing (referred to as CMP below), for example, until the plurality of hard masks 71 are exposed. The plurality of hard masks 71 function as a polishing stopper to stop the polishing.

FIG. 18 shows the next step. In this step, the insulating layer 23 is etched so that the distance between the top surface 21a of the substrate 21 and the top surface of the insulating layer 23 is smaller than the distance between the top surface 21a of the substrate 21 and the top surfaces of the plurality of hard masks 71. This etching is performed by wet etching using alkaline developer, or IBE, for example.

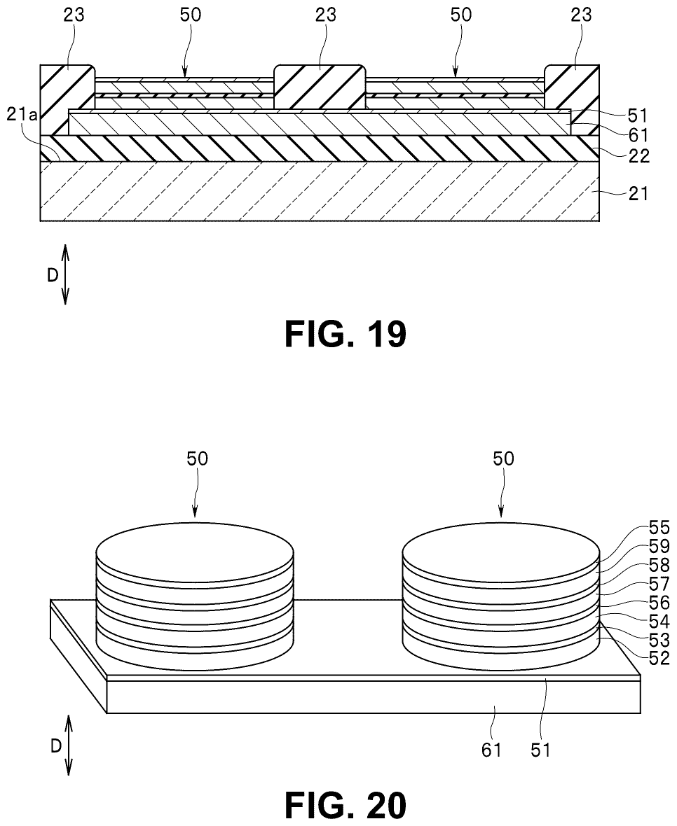

FIG. 19 shows the next step. In this step, the plurality of hard masks 71 are removed. When the plurality of hard masks 71 are formed of carbon, the plurality of hard masks 71 are removed by plasma ashing using ashing gas containing O₂, for example. By removing the plurality of hard masks 71, a plurality of contact holes for connecting the plurality of MR elements 50 to the plurality of upper electrodes 62 are formed in the insulating layer 23.

Then, the upper electrodes 62 are formed. In this way, the magnetoresistive device 10 is completed. Note that, after the upper electrodes 62 are formed, a not-shown insulating layer may be formed to cover the stack.

As described above, the method for manufacturing the magnetoresistive device 10 according to the example embodiment includes the step of forming the layered film 50P, the step of forming the plurality of hard masks 71 on the layered film 50P, the step of etching, by using the plurality of hard masks 71, the layered film 50P so that the layered film 50P becomes the plurality of MR elements 50, the step of forming the insulating layer 23 around the plurality of MR elements 50, the step of removing the plurality of hard masks 71, and the step of forming the plurality of upper electrodes 62. The method for manufacturing the magnetoresistive device 10 further includes the step of forming the plurality of lower electrodes 61.

Next, the operation and effects of the magnetoresistive device 10 according to the example embodiment will be described. According to the example embodiment, the taper of the side surface 50c of each of the MR elements 50 can be made small compared to that of a case where the layered film 50P is etched without using the plurality of hard masks 71. Here, a method for manufacturing the magnetoresistive device 10 in which the layered film 50P is etched without using the plurality of hard masks 71 is referred to as a method for manufacturing a magnetoresistive device of a first comparative example. In the method for manufacturing a magnetoresistive device of the first comparative example, a plurality of photoresist masks are used as etching masks instead of the plurality of hard masks 71, to etch the layered film 50P.

Since the etching rate of photo resist masks is higher than the etching rate of the hard masks 71, the thickness of the photoresist masks need be large to some extent. However, when the photoresist masks have a large thickness, it is difficult to incline the traveling direction of ion beams to remove a re-deposited film. To address this, in the first comparative example, the distance between each two adjacent MR elements 50 need be large. This makes it difficult to increase the number of MR elements 50 per unit area in the first comparative example.

When the traveling direction of ion beams is inclined, the photoresist masks are etched, which consequently make the taper of the side surface 50c of each MR element 50 large. In this case, when a comparison is made with the top surfaces 50b of the MR elements 50 being the same in size and also the distance between the bottom surfaces 50a of each two MR elements 50 being the same, the number of MR elements 50 per unit area decreases as the taper of the side surface 50c of each MR element 50 becomes larger. This also makes it difficult to increase the number of MR elements 50 per unit area in the first comparative example.

In contrast to this, according to the example embodiment, by using the hard masks 71 as etching masks, the thickness of the etching masks can be made small compared to that in the first comparative example. Hence, according to the example embodiment, the distance between each two adjacent MR elements 50 can be made small. According to the example embodiment, it is also possible to suppress etching of etching masks when the traveling direction of ion beams is inclined. Hence, according to the example embodiment, the taper of the side surface 50c of each MR element 50 can be made small. In view of these, according to the example embodiment, it is possible to increase the number of the MR elements 50 per unit area.

Meanwhile, as the photoresist masks, photoresist masks each including a lower layer and an upper layer disposed on the lower layer are used, for example. The upper layer is formed by photoresist patterned by photolithography. The lower layer is formed of a material dissolved by developer used for patterning of the upper layer, for example. The photoresist masks thus formed have undercuts forming space between the photoresist masks and a foundation. When the photoresist masks thus formed are used as etching masks, and the traveling direction of ion beams is inclined, the top surface of each MR element 50 and a portion near the top surface may be etched to damage the free layer 54. In contrast to this, according to the example embodiment, by using the hard masks 71 as etching masks, it is possible to prevent the free layer 54 from being damaged.

In the example embodiment, each upper electrode 62 includes the connection portions 621. Each connection portion 621 has a contact surface 621a being in contact with a corresponding one of the MR elements 50 and a circumferential surface 621b connected to the contact surface 621a. Here, consider a magnetoresistive device of a second comparative example in which upper electrodes are connected to MR elements via contact holes provided in an insulating layer covering the MR elements. To reduce the resistance of the entire magnetoresistive device, it is necessary to enlarge the contact holes in the insulating layer to increase the contact area of the MR elements and the upper electrodes. However, from the viewpoint of alignment precision of photoresist masks used in the manufacturing of the magnetoresistive device and the like, the plane shapes of the MR elements need to be made larger than the plane shapes of the contact holes to some extent. For this reason, according to a comparison made with contact holes being the same in size, it is difficult to increase the number of MR elements per unit area in the second comparative example.

In the second comparative example, to securely connect the upper electrodes to the MR elements, it is necessary to make the plane shapes of the upper electrodes larger than the plane shapes of the contact holes, to completely fill the contact holes. For this reason, according to a comparison made with the contact holes being the same in size, it is difficult to reduce the distance between two adjacent upper electrodes and consequently difficult to reduce the distance between each two MR elements, in the second comparative example. Also for this reason, according to the second comparative example, it is difficult to increase the number of MR elements per unit area.

In contrast, in the example embodiment, each contact surface 621a has a shape identical to that of the free layer 54 of the corresponding MR element 50 when seen in the stacking direction D. Such a shape can be enabled by the method for manufacturing the magnetoresistive device 10 according to the example embodiment. In a comparison made with the contact surfaces 621a being the same in size, according to the example embodiment, the size of each MR element 50 can be made small, and consequently, the number of the MR elements 50 per unit area can be increased, compared to those in the second comparative example.

### Modification Example

Next, first and second modification examples of the MR elements 50 and a modification example of the upper electrodes 62 in the example embodiment will be described. First, the first modification example will be described with reference to FIG. 20. FIG. 20 is a perspective view showing the first modification example of the MR elements 50. In the first modification example, each MR element 50 includes a non-magnetic metal layer 56, a magnetization pinned layer 57, a gap layer 58, and a free layer 59 in addition to the buffer layer 51, the magnetization pinned layer 52, the gap layer 53, the free layer 54, and the cap layer 55. The non-magnetic metal layer 56, the magnetization pinned layer 57, the gap layer 58, and the free layer 59 are stacked in this order on the free layer 54. The cap layer 55 is disposed on the free layer 59.

The configurations of the magnetization pinned layer 57, the gap layer 58, and the free layer 59 may be the same as the configurations of the magnetization pinned layer 52, the gap layer 53, and the free layer 54, respectively. The non-magnetic metal layer 56 is formed of a non-magnetic metallic material such as Ru, Ta, Cu or Cr, for example, for example.

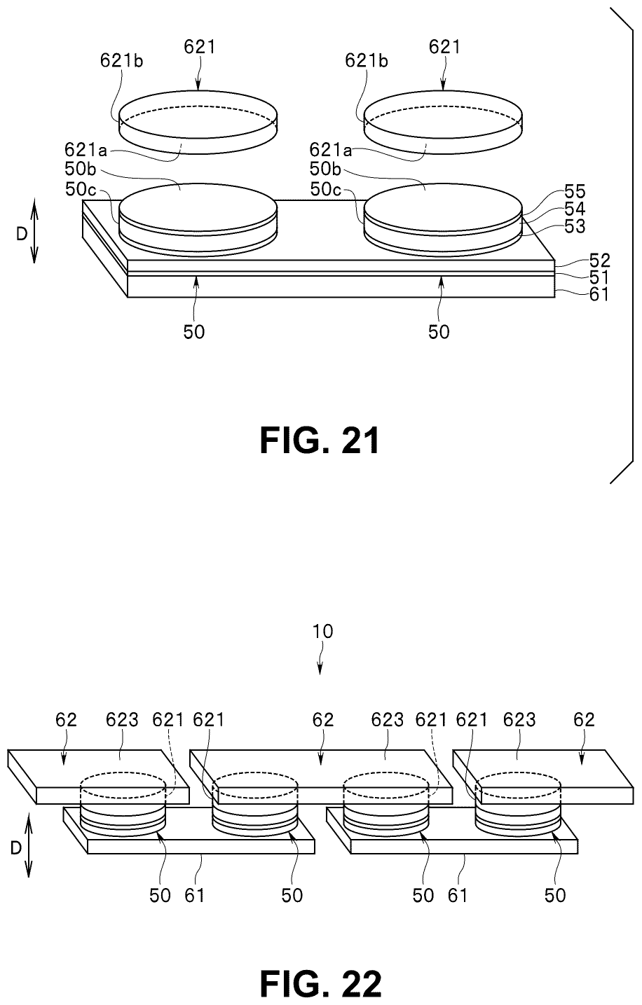

Next, the second modification example will be described with reference to FIG. 21. FIG. 21 is a perspective view showing the second modification example of the MR elements 50. In the second modification example, the shape of the magnetization pinned layer 52 is different from that of the example shown in FIG. 1, FIG. 2, and FIG. 4. As shown in FIG. 21, the magnetization pinned layer 52 has a shape so that one magnetization pinned layer 52 overlaps two free layers 54 when seen in the stacking direction D. The plane shape of the magnetization pinned layer 52 may be the same as that of the buffer layer 51.

On the magnetization pinned layer 52, two stacks each composed of the gap layer 53, the free layer 54, and the cap layer 55 are disposed. In the second modification example, the one magnetization pinned layer 52 is used for two MR elements 50 in common.

In the second modification example, each MR element 50 includes the magnetization pinned layer 52 as a portion having a shape larger than that of the connection portion 621 of the corresponding upper electrode 62 when seen in the stacking direction D.

Next, the modification example of the upper electrodes 62 will be described with reference to FIG. 22. FIG. 22 is a perspective view showing the modification example of the upper electrodes 62. In this modification example, each upper electrode 621 includes a joining portion 623 instead of the joining portion 622 shown in FIG. 1. The joining portion 623 joins two connection portions 621. The plane shape of the joining portion 623 is a rectangle being long in one direction. The shorter-side direction dimension of the joining portion 623 may be larger than the diameter of the plane shape of the connection portion 621.

### Second Example Embodiment

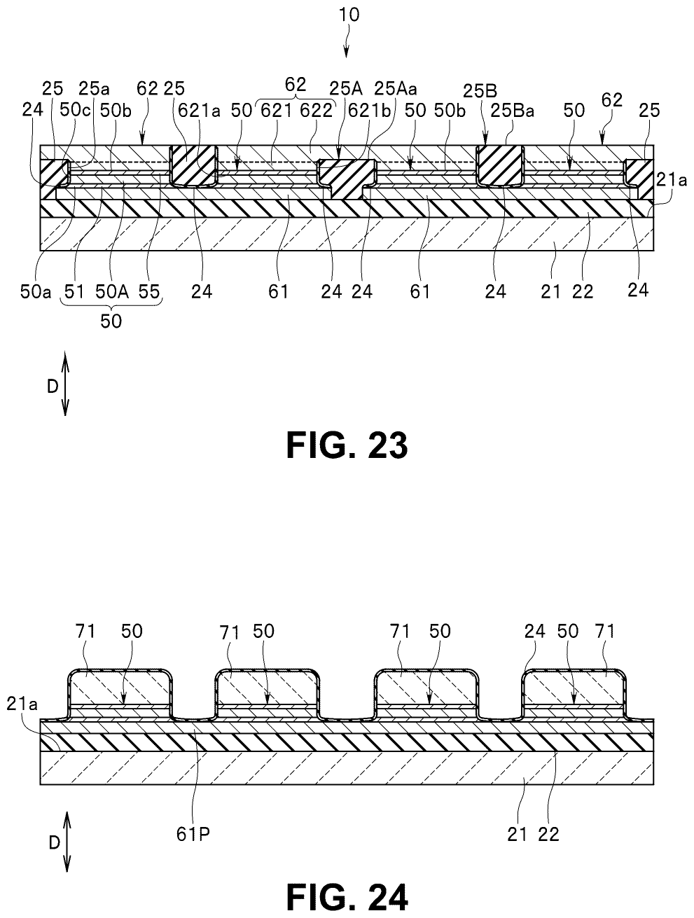

Next, a second example embodiment of the technology will be described. First, description will be given of respects of a configuration of a magnetoresistive device 10 according to the example embodiment different from those in the first example embodiment, with reference to FIG. 23. FIG. 23 is a cross-sectional view showing a part of the magnetoresistive device 10 according to the example embodiment.

In the example embodiment, the plane shape of the buffer layer 51 of each MR element 50 is the same or substantially the same as the plane shape of the magnetization pinned layer 52 of the MR element 50.

The magnetoresistive device 10 according to the example embodiment includes an insulating film 24 and an insulating layer 25 instead of the insulating layer 23 in the first example embodiment. The insulating layer 25 is disposed around the MR elements 50, the lower electrodes 61, and the connection portions 621 of the upper electrodes 62. The insulating film 24 is disposed between the MR elements 50, the lower electrodes 61, and the connection portions 621, and the insulating layer 25. The insulating film 24 and the insulating layer 25 are formed of SiO₂ or Al₂O₃, for example.

The insulating layer 25 has a facing surface 25a facing the side surface 50c of each MR element 50 and the circumferential surface 621b of a corresponding one of the connection portions 621. In the example embodiment, in particular, the facing surface 25a faces the side surface 50c and the circumferential surface 621b with the insulating film 24 interposed therebetween. The angle of at least a part of the facing surface 25a with respect to the stacking direction D is within a range of 0° to 7°, for example.

The insulating layer 25 includes a first portion 25A and a second portion 25B that are arranged to sandwich one MR element 50 and one connection portion 621 connected this one MR element. The first portion 25A is one end in the stacking direction D and has an end portion 25Aa located at one end furthest from the substrate 21. The second portion 25B is one end in the stacking direction D and has an end portion 25Ba located at one end furthest from the substrate 21. The end portion 25Aa and the end portion 25Ba are at positions different from each other in the stacking direction D. In the example shown in FIG. 23, the end portion 25Aa is disposed at a position closer to the top surface 21a of the substrate 21 than the end portion 25Ba is. In other words, the distance between the end portion 25Aa and the top surface 21a of the substrate 21 is smaller than the distance between the end portion 25Ba and the top surface 21a of the substrate 21.

The end portion 25Aa of the first portion 25A and the end portion 25Ba of the second portion 25B are disposed at a position further from the top surface 21a of the substrate 21 than the top surface 50b of the MR element 50 is. The insulating film 24 and the insulating layer 25 are not in contact with the top surface 50b of each MR element 50. In the example shown in FIG. 23, the distance between the end portion 25Aa and the top surface 21a of the substrate 21 is larger than the distance between the top surface 50b of the MR element 50 and the top surface 21a of the substrate 21.

On the end portion 25Aa of the first portion 25A, the joining portion 622 of the corresponding upper electrode 62 is disposed. On the end portion 25Ba of the second portion 25B, no portion of the upper electrode 62 is disposed.

Next, a method for manufacturing the magnetoresistive device 10 according to the example embodiment will be described with reference to FIG. 24 to FIG. 29. FIG. 24 to FIG. 29 show cross-sectional views in a process of manufacturing the magnetoresistive device 10.

The method for manufacturing the magnetoresistive device 10 according to the example embodiment is similar to that of the first example embodiment to the step of etching the layered film 50P to form form the plurality of MR elements 50 (refer to FIG. 12). Note that, in the example embodiment, the etching of the layered film 50P may be performed until the metal layer 61P is exposed, for example. FIG. 24 shows the next step. In this step, the insulating film 24 is formed on the entire top surface of a stack by an atomic layer deposition method (referred to as ALD below), for example. The thickness of the insulating film 24 is in a range of 10 to 20 nm, for example.

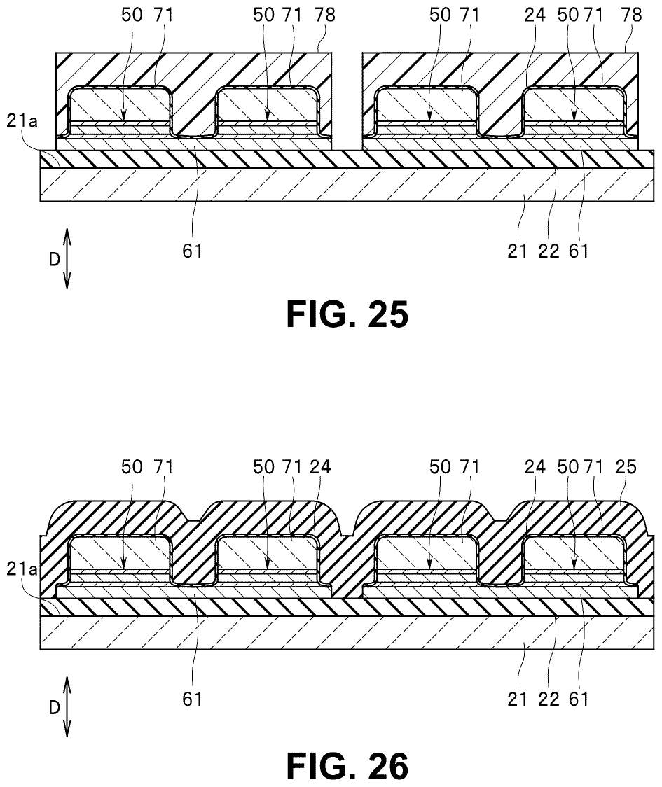

FIG. 25 shows the next step. In this step, first, a plurality of photoresist masks 78 are formed to cover the plurality of MR elements 50 and the plurality of hard masks 71. The plurality of photoresist masks 78 have a plane shape corresponding to the lower electrodes 61. Then, by using the plurality of photoresist masks 78 as etching masks, the metal layer 61P is etched by RIE or IBE, for example, so that the metal layer 61P becomes the plurality of lower electrodes 61. Then, the plurality of photoresist masks 78 are removed.

FIG. 26 shows the next step. In this step, the insulating layer 25 is formed on the entire top surface of a stack. The insulating layer 25 is also formed around the plurality of MR elements 50 and the plurality of lower electrodes 61.

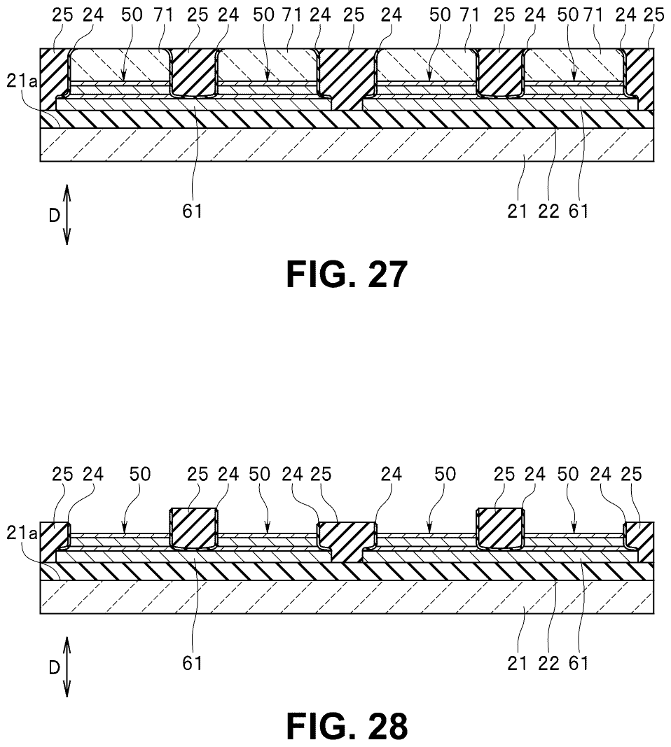

FIG. 27 shows the next step. In this step, the insulating film 24 and the insulating layer 25 are polished by CMP, for example, until the plurality of hard masks 71 are exposed. The plurality of hard masks 71 function as a polishing stopper to stop the polishing.

FIG. 28 shows the next step. In this step, first, a not-shown photoresist mask is formed on the stack. The insulating layer 25 includes a plurality of portions to be etched. Each of the plurality of portions to be etched are disposed between two MR elements 50 to be connected by each upper electrode 62. The not-shown photoresist mask includes a plurality of openings for exposing the plurality of portions to be etched. Then, by using the not-shown photoresist mask as an etching mask, the plurality of portions to be etched are etched by RIE, for example. To etch the plurality of portions to be etched by RIE, gas containing HCl and BCl₃ may be used as etching gas, for example. In this etching, the insulating film 24 adjacent to the plurality of portions to be etched is also etched.

Then, the photoresist mask is removed. Then, the insulating layer 25 is etched so that the distance between the top surface 21a of the substrate 21 and the top surface of the insulating layer 25 becomes smaller than the distance between the top surface 21a of the substrate 21 and the top surfaces of the plurality of hard masks 71. This etching is performed by wet etching using alkaline developer, or IBE, for example. Then, the plurality of hard masks 71 are removed. When the plurality of hard masks 71 are formed of carbon, the plurality of hard masks 71 are removed by plasma ashing using ashing gas containing O₂, for example.

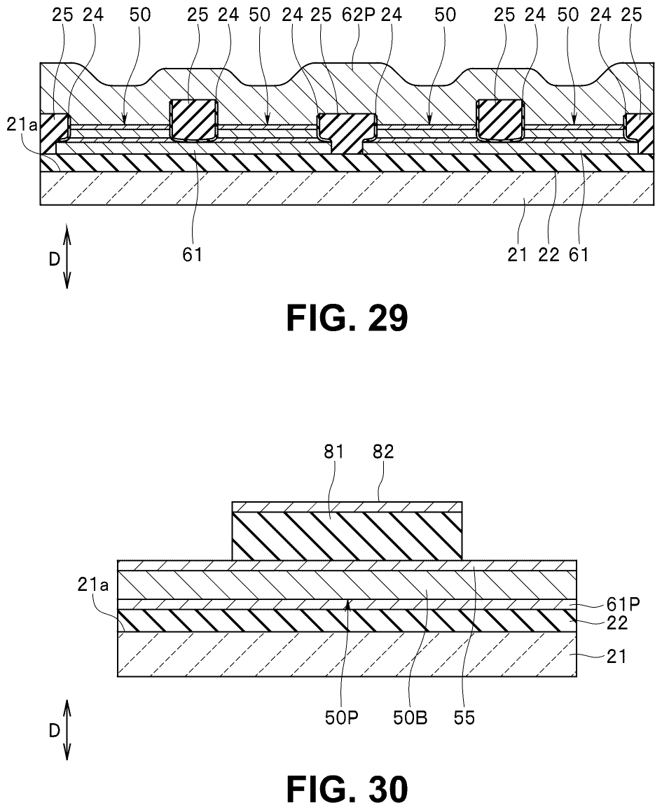

FIG. 29 shows the next step. In this step, on the stack, a metal layer 62P to later become the plurality of upper electrodes 62 is formed.

Then, by CMP or an etch back method using resist, for example, a part of the metal layer 62P is removed so that the metal layer 62P becomes the plurality of upper electrodes 62. In this way, the magnetoresistive device 10 is completed.

The configuration, operation, and effects of the example embodiment are otherwise the same as those of the first example embodiment.

### Third Example Embodiment

Next, a method for manufacturing a magnetoresistive device according to a third example embodiment of the technology will be described with reference to FIG. 30 to FIG. 37. FIG. 30 to FIG. 37 show cross-sectional views in a process of manufacturing the magnetoresistive device 10 according to the example embodiment.

The method for manufacturing the magnetoresistive device 10 according to the example embodiment is similar to that of the first example embodiment to the step of forming the layered film 50P. FIG. 30 shows the next step. In this step, first, a hard mask material layer is formed. In the example embodiment, in particular, the hard mask material layer is formed of Al₂O₃. Then, on the hard mask material layer, a non-magnetic metal layer 82 formed of Ta, for example, is formed. Then, on the non-magnetic metal layer 82, a not-shown plurality of photoresist masks are formed. The not-shown plurality of photoresist masks have a plane shape corresponding to the MR elements 50.

Then, by using the not-shown plurality of photoresist masks as etching masks, the non-magnetic metal layer 82 is etched by RIE or IBE. Then, by using the non-magnetic metal layer 82 and the plurality of photoresist masks as etching masks, the hard mask material layer is etched by RIE, for example, so that the hard mask material layer becomes a plurality of hard masks 81. Then, the not-shown plurality of photoresist masks are removed.

Note that, in FIG. 30, the reference sign 50B indicates a layered film composed of the buffer layer 51, the magnetization pinned layer 52, the gap layer 53, and the free layer 54.

FIG. 31 shows the next step. In this step, first, by using the plurality of hard masks 81 as etching masks, the layered film 50P is etched by IBE, for example, so that the layered film 50P becomes the plurality of MR elements 50. This etching may be performed until the metal layer 61P is exposed, for example. In this etching, the non-magnetic metal layer 82 is also etched. Then, the insulating film 26 is formed on the entire top surface of a stack. The insulating film 26 is formed of SiO₂, for example.

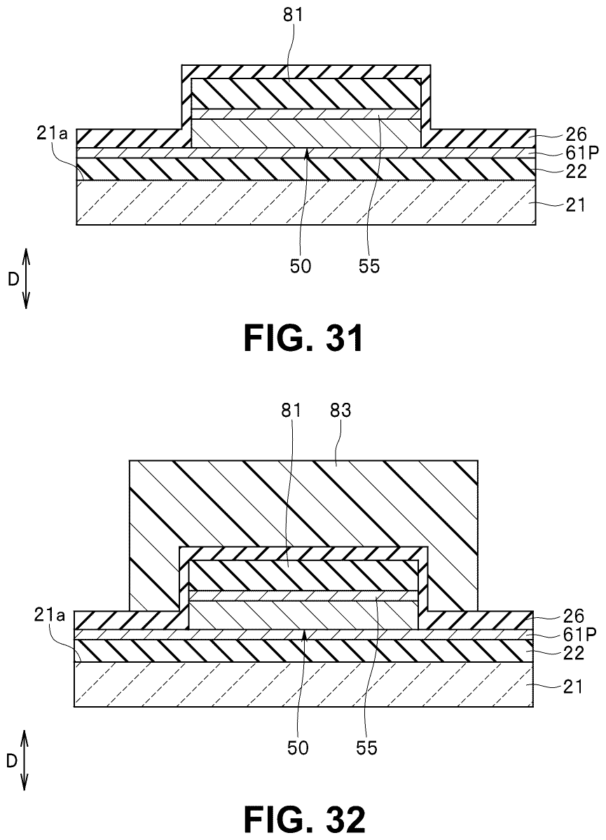

FIG. 32 shows the next step. In this step, a plurality of photoresist masks 83 are formed to cover the plurality of MR elements 50 and the plurality of hard masks 81. The plurality of photoresist masks 83 have a plane shape corresponding to the lower electrodes 61.

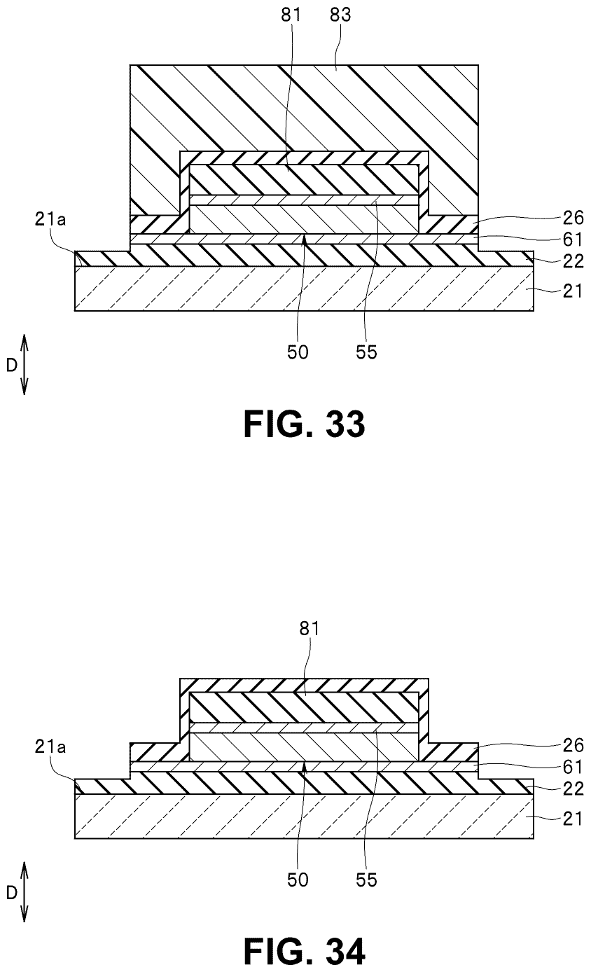

FIG. 33 shows the next step. In this step, by using the plurality of photoresist masks 83 as etching masks, the metal layer 61P is etched by RIE or IBE, for example, so that the metal layer 61P becomes the plurality of lower electrodes 61. Then, as shown in FIG. 34, the plurality of photoresist masks 83 are removed.

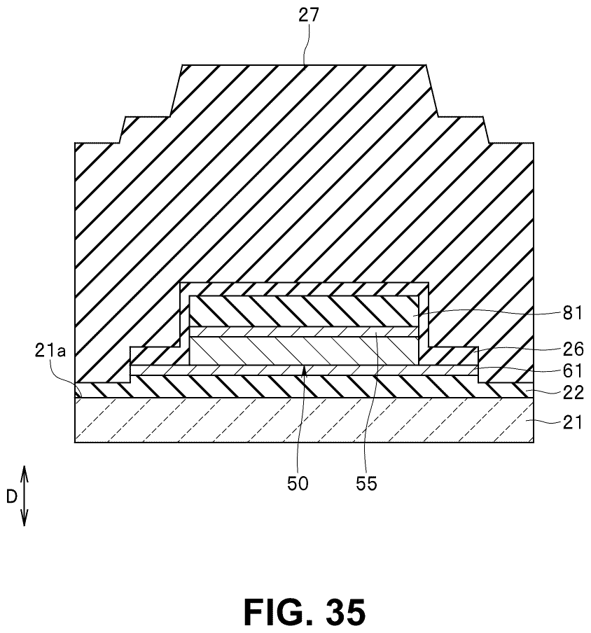

FIG. 35 shows the next step. In this step, the insulating layer 27 is formed on the entire top surface of a stack. The insulating layer 27 is also formed around the plurality of MR elements 50 and the plurality of lower electrodes 61. The insulating layer 27 is formed of SiO₂, for example.

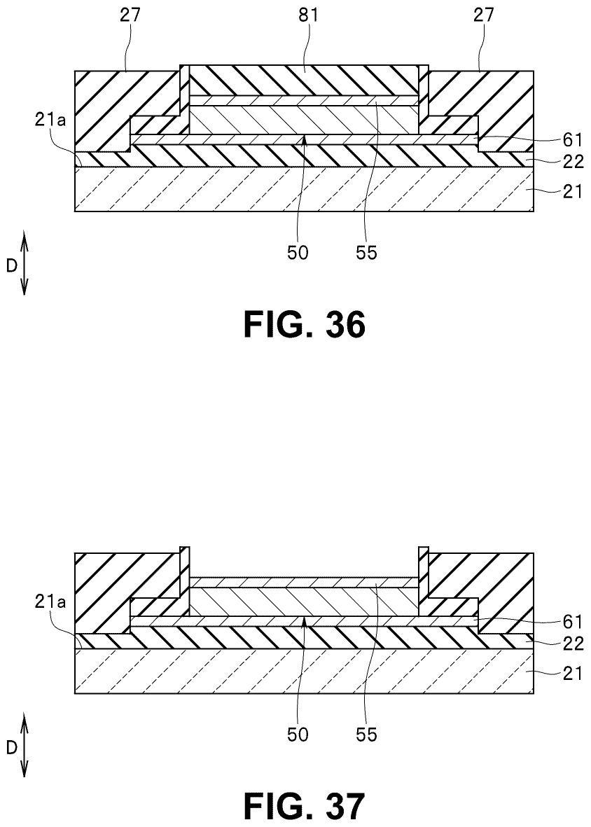

FIG. 36 shows the next step. In this step, the insulating film 26 and the insulating layer 27 are polished by CMP, for example, until the plurality of hard masks 81 are exposed.

FIG. 37 shows the next step. In this step, the plurality of hard masks 81 are removed by etching.

Then, the upper electrodes 62 are formed. In this way, the magnetoresistive device 10 is completed.

The configuration, operation, and effects of the example embodiment are otherwise the same as those of the first example embodiment.

### Fourth Example Embodiment

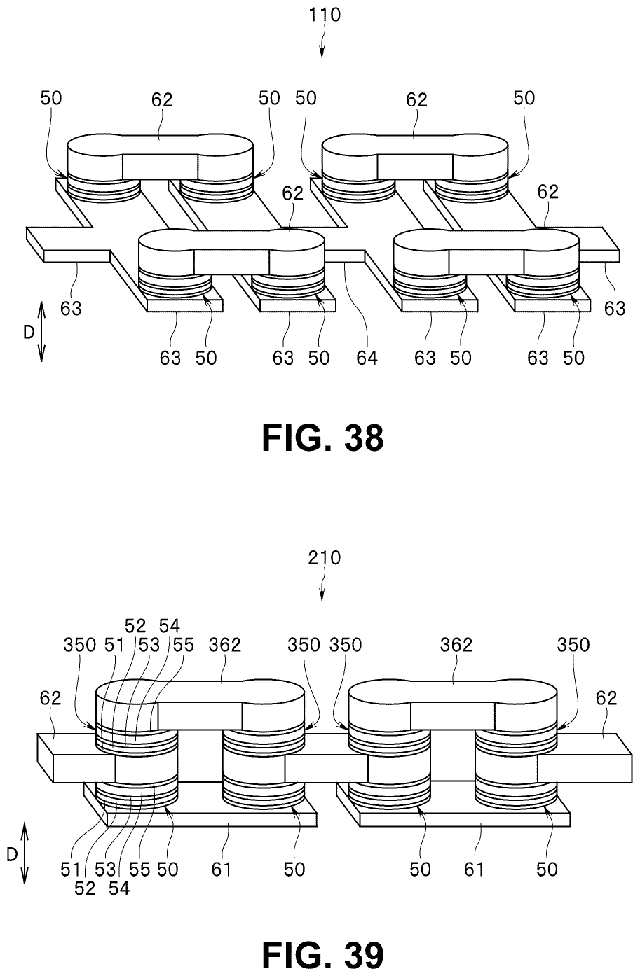

Next, a fourth example embodiment of the technology will be described with reference to FIG. 38. FIG. 38 is a perspective view showing a part of a magnetoresistive device according to the example embodiment.

A configuration of a magnetoresistive device 110 according to the example embodiment is different from the configuration of the magnetoresistive device 10 according to the first example embodiment, in the following respects. The magnetoresistive device 110 includes a plurality of lower electrodes 63 and a plurality of connection electrodes 64 instead of the plurality of lower electrodes 61 in the first example embodiment. The plurality of lower electrodes 63 and the plurality of connection electrodes 64 are formed of Au, Cu, or Ta, for example.

Each lower electrode 63 has a long slender shape. There is a gap formed between each two lower electrodes 63 adjacent in the shorter-side direction of the lower electrodes 63. The MR elements 50 are disposed on the top surface of each lower electrode 63, near both ends in the longitudinal direction. Each upper electrode 62 electrically connects two adjacent MR elements 50 disposed on two lower electrodes 61 adjacent in the shorter-side direction of the lower electrodes 61.

A pair of two MR elements 50 connected in series by one upper electrode 62 and a pair of two other MR elements 50 connected in series by one different upper electrode 62 are connected in parallel by two lower electrodes 63. Each connection electrode 64 connects two lower electrodes 61 adjacent to each other in a shorter-side direction of the lower electrodes 61 and two lower electrodes 63 not electrically connected by two upper electrodes 62.

The configuration, operation, and effects of the example embodiment are otherwise the same as those of the first example embodiment.

### Fifth Example Embodiment

Next, a fifth example embodiment of the technology will be described with reference to FIG. 39. FIG. 39 is a perspective view showing a part of a magnetoresistive device according to the example embodiment.

A configuration of a magnetoresistive device 210 according to the example embodiment is different from the configuration of the magnetoresistive device 10 according to the first example embodiment, in the following respects. The magnetoresistive device 210 includes a plurality of MR elements 350 and a plurality of upper electrodes 362 in addition to the plurality of MR elements 50, the plurality of lower electrodes 61, and the plurality of upper electrodes 62 in the first example embodiment.

The configuration of each of the plurality of MR elements 350 is the same as the configuration of each MR element 50. Specifically, each of the plurality of MR elements 350 includes the buffer layer 51, the magnetization pinned layer 52, the gap layer 53, the free layer 54, and the cap layer 55. In the example shown in FIG. 39, the stacking order of the buffer layer 51, the magnetization pinned layer 52, the gap layer 53, the free layer 54, and the cap layer 55 of each MR element 350 is the same as that of each MR element 50.

The MR elements 350 are disposed on the top surface of each upper electrode 62, near both ends in the longitudinal direction. Each upper electrode 362 has a long slender shape and electrically connects two adjacent MR elements 350 disposed on two upper electrodes 62 adjacent in the longitudinal direction of the upper electrodes 62.

The configuration of the plurality of upper electrodes 362 is the same as the configuration of the plurality of upper electrodes 62. The plurality of upper electrodes 362 may be formed of the same material as that of the plurality of upper electrodes 62. The relationship between the plurality of MR elements 350 and the plurality of upper electrodes 362 is the same as the relationship between the plurality of MR elements 50 and the plurality of upper electrodes 62.

The configuration, operation, and effects of the example embodiment are otherwise the same as those of the first example embodiment.

### Modification Example

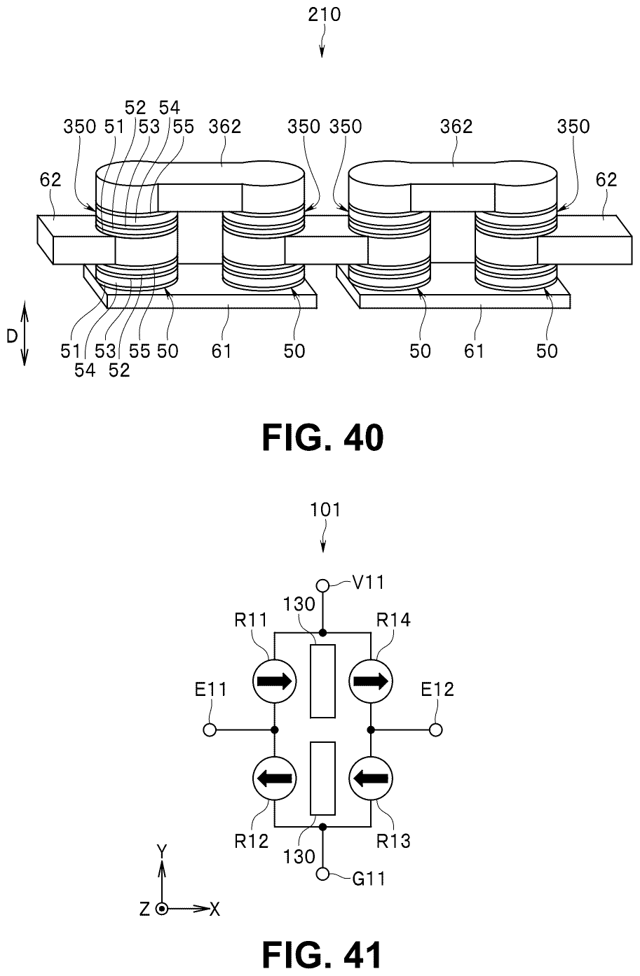

Next, a modification example of the magnetoresistive device 210 will be described with reference to FIG. 40. FIG. 40 is a perspective view showing a part of the modification example of the magnetoresistive device 210. In the modification example, the stacking order of the buffer layer 51, the magnetization pinned layer 52, the gap layer 53, the free layer 54, and the cap layer 55 of each MR element 50 is different from that of the example shown in FIG. 39. Specifically, in the modification example, the buffer layer 51, the magnetization pinned layer 52, the gap layer 53, the free layer 54, and the cap layer 55 of the MR element 50 are stacked in the order of the buffer layer 51, the free layer 54, the gap layer 53, the magnetization pinned layer 52, and the cap layer 55 from the lower electrode 61 side.

### Sixth Example Embodiment

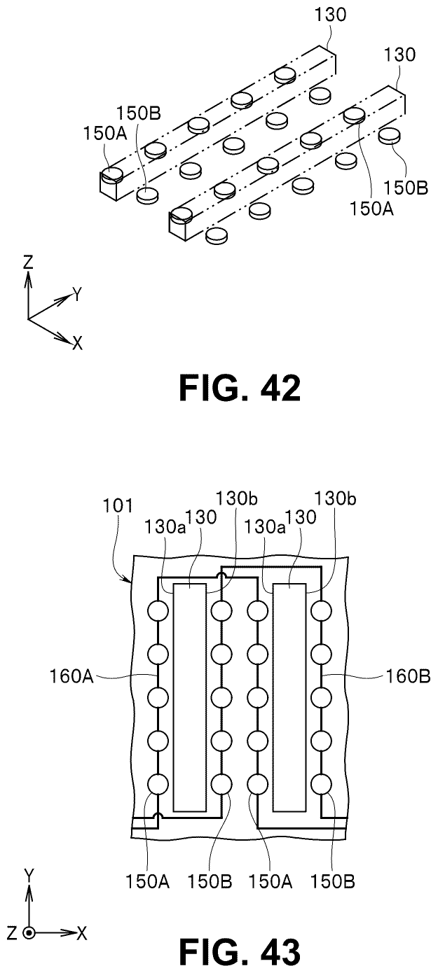

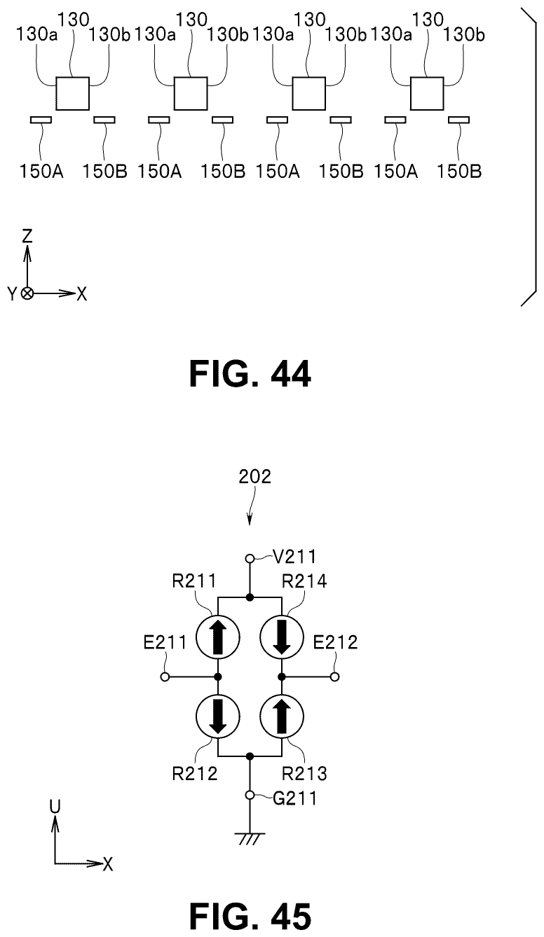

Next, a magnetic sensor according to a sixth example embodiment of the technology will be described with reference to FIG. 41 to FIG. 44. FIG. 41 is a circuit diagram showing a circuit configuration of the magnetic sensor according to the example embodiment. FIG. 42 is a perspective view showing a part of the magnetic sensor according to the example embodiment. FIG. 43 is a plan view showing a part of the magnetic sensor according to the example embodiment. FIG. 44 is a side view showing a part of the magnetic sensor according to the example embodiment.

A magnetic sensor 101 according to the example embodiment includes four resistance portions R11, R12, R13, and R14, a power supply port V11, a ground port G11, and two output ports E11 and E12. The resistance portion R11 is provided between the power supply port V11 and the output port E11. The resistance portion R12 is provided between the output port E11 and the ground port G11. The resistance portion R13 is provided between the output port E12 and the ground port G11. The resistance portion R14 is provided between the power supply port V11 and the output port E12. A voltage or current of predetermined magnitude is applied to the power supply port V11. The ground port G11 is grounded.

Each of the resistance portions R11 to R14 is constituted by using the magnetoresistive device 10 according to any of the first to third example embodiments. In each of the resistance portions R11 to R14, the plurality of MR elements 50 of the magnetoresistive device 10 are connected in series.

In FIG. 41, an arrow illustrated to overlap each of the resistance portions R11 to R14 indicates the direction of the magnetization 52m (refer to FIG. 5) of the magnetization pinned layer 52 of each MR element 50 in each of the resistance portions R11 to R14. In the example shown in FIG. 41, the direction of the magnetization 52m of the magnetization pinned layer 52 of each MR element 50 in each of the resistance portions R11 and R14 is the X direction. The direction of the magnetization 52m of the magnetization pinned layer 52 of each MR element 50 in each of the resistance portions R12 and R13 is the −X direction.

The magnetic sensor 101 further includes a plurality of yokes 130 each formed of a soft magnetic material. Each of the plurality of yokes 130 is configured to receive an input magnetic field including an input magnetic field component in a direction parallel to the Z direction and generate an output magnetic field including an output magnetic component in a direction parallel to the X direction. Each of the plurality of yokes 130 has a rectangular solid shape long in the Y direction, for example. The plurality of yokes 130 are arranged in the direction parallel to the X direction.

Each yoke 130 has a first end surface 130a and a second end surface 130b located opposite to each other. The first end surface 130a is located at the end in the −X direction of the yoke 130, and the second end surface 130b is located at the end in the X direction of the yoke 130.

Each of the plurality of MR elements 50 is located at a position where the output magnetic field component generated by the corresponding yoke 130 can be detected. In the example shown in FIG. 42 to FIG. 44, each of the plurality of MR elements 50 is located near the end portion of the corresponding yoke 130 in the −Z direction. The plurality of MR elements 50 include a plurality of MR elements 50 arranged along the first end surface 130a and a plurality of MR elements 50 arranged along the second end surface 130b. The plurality of MR elements 50 arranged along the first end surface 130a will be denoted by the reference sign 150A, and the plurality of MR elements 50 arranged along the second end surface 130b will be denoted by the reference sign 150B, below.

In FIG. 43, the reference signs 160A and 160B denote wiring portions composed of the plurality of lower electrodes 61 and the plurality of upper electrodes 62 (refer to FIG. 1 to FIG. 4). The wiring portion 160A connects the plurality of MR elements 150A in series. The wiring portion 160B connects the plurality of MR elements 150B in series. The magnetic sensor 101 further includes a plurality of first element arrays, a plurality of second element arrays, and a plurality of connection electrodes. Each of the plurality of first element arrays includes a plurality of MR elements 150A arranged in a line along the first end surface 130a. Each of the plurality of second element arrays includes a plurality of MR elements 150B arranged in a line along the second end surface 130b. The plurality of connection electrodes electrically connect the plurality of lower electrodes 61 or the plurality of upper electrodes 62 so that the plurality of first element arrays are connected in series and also electrically connect the plurality of lower electrodes 61 or the plurality of upper electrodes 62 so that the plurality of second element arrays are connected in series.

The resistance portion R11 is composed of a plurality of MR elements 150A each having the direction of the magnetization 52m of the magnetization pinned layer 52 being the X direction. The resistance portion R12 is composed of a plurality of MR elements 150A each having the direction of the magnetization 52m of the magnetization pinned layer 52 being the −X direction. The resistance portion R13 is composed of a plurality of MR elements 150B each having the direction of the magnetization 52m of the magnetization pinned layer 52 being the −X direction. The resistance portion R14 is composed of the plurality of MR elements 150B each having the direction of the magnetization 52m of the magnetization pinned layer 52 being the X direction.

Next, at least one detection signal generated by the magnetic sensor 101 will be described in detail with reference to FIG. 41. When the direction of the input magnetic field component is the Z direction, the direction of the output magnetic field component that the plurality of MR elements 150A composing the resistance portions R11 and R12 receive is the X direction, and the direction of the output magnetic field component that the plurality of MR elements 150B composing the resistance portions R13 and R14 receive is the −X direction. In this case, in the free layer 54 of each of the plurality of MR elements 150A composing the resistance portions R11 and R12, the center 54c of the magnetic vortex structure moves, and also the amount of the magnetization 54m in the X direction becomes larger than the amount of the magnetization 54m in the −X direction (refer to FIG. 7). Moreover, in this case, in the free layer 54 of each of the plurality of MR elements 150B composing the resistance portions R13 and R14, the center 54c of the magnetic vortex structure moves, and also the amount of the magnetization 54m in the −X direction becomes larger than the amount of the magnetization 54m in the X direction (refer to FIG. 8). As a result, the resistance of each of the plurality of MR elements 150A composing the resistance portion R11 and the plurality of MR elements 150B composing the resistance portion R13 decreases, and the resistance of each of the resistance portions R11 and R13 also decreases, compared to a state where no output magnetic field component is present. Moreover, the resistance of each of the plurality of MR elements 150A composing the resistance portion R12 and the plurality of MR elements 150B composing the resistance portion R14 increases, and the resistance of each of the resistance portions R12 and R14 also increases, compared to a state where no output magnetic field component is present.

When the direction of the input magnetic field component is the −Z direction, the direction of the output magnetic field component and the change of the resistance of each of the resistance portions R11 to R14 are reverse to those of the case where the direction of the input magnetic field component is the Z direction described above.

The amount of change in the resistance of each of the MR elements 150A and 150B depends on the strength of the output magnetic field component that the corresponding one of the MR elements 150A and 150B receives. As the strength of the output magnetic field component increases, the resistance of each of the MR elements 150A and 150B changes so that the amount of increase or the amount of decrease increases. As the strength of the output magnetic field component decreases, the resistance of each of the MR elements 150A and 150B changes so that the amount of increase or the amount of decrease decreases. The strength of the output magnetic field component depends on the strength of the input magnetic field component.

As described above, when the direction and strength of the input magnetic field component change, the resistance of each of the resistance portions R11 to R14 changes so that the resistance of each of the resistance portions R11 and R13 increases and the resistance of each of the resistance portions R12 and R14 decreases, or so that the resistance of each of the resistance portions R11 and R13 decreases and the resistance of each of the resistance portions R12 and R14 increases. Consequently, the potential of each of the output ports E11 and E12 shown in FIG. 41 changes. The magnetic sensor 101 generates two signals corresponding to the potentials at the output ports E11 and E12 or a signal corresponding to the potential difference between the output ports E11 and E12, as at least one detection signal. The at least one detection signal has a correspondence with the strength of the input magnetic field component.

The configuration, operation, and effects of the example embodiment are otherwise the same as those of any of the first to third example embodiments.

### Seventh Example Embodiment

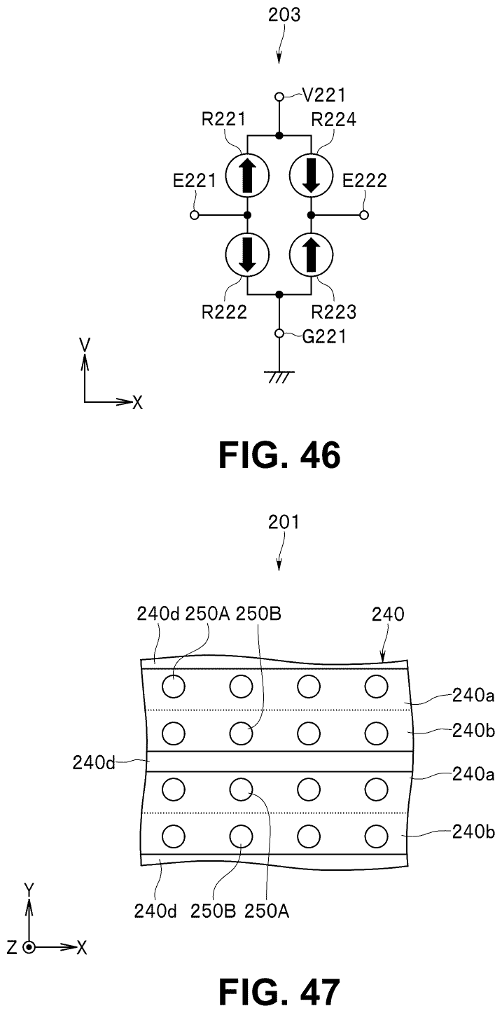

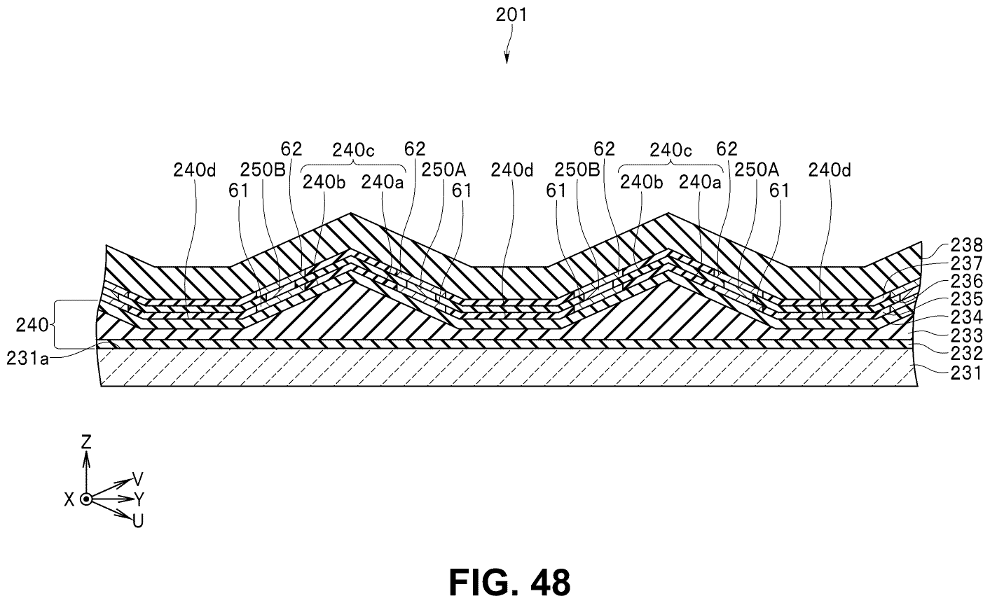

Next, a magnetic sensor according to a seventh example embodiment of the technology will be described with reference to FIG. 45 to FIG. 48. FIG. 45 is a circuit diagram showing a circuit configuration of a first detection circuit of the magnetic sensor according to the example embodiment. FIG. 46 is a circuit diagram showing a circuit configuration of a second detection circuit of the magnetic sensor according to the example embodiment. FIG. 47 is a plan view showing a part of the magnetic sensor according to the example embodiment. FIG. 48 is a cross-sectional view showing a part of the magnetic sensor according to the example embodiment.

First, with reference to FIG. 48, a U direction and a V direction will be defined. The U direction is a direction obtained by rotating from the Y direction toward the −Z direction. The V direction is a direction obtained by rotating from the Y direction toward the Z direction. In the example embodiment, in particular, the U direction is defined as a direction obtained by rotating by a from the Y direction toward the −Z direction, and the V direction is defined as a direction obtained by rotating by a from the Y direction toward the Z direction. Note that α is an angle larger than 0° and smaller than 90°. The opposite directions to the U direction and the V direction are defined as a −U direction and a −V direction, respectively. The U direction and the V direction are each orthogonal to the X direction.

The magnetic sensor 201 according to the example embodiment includes a first detection circuit 202 and a second detection circuit 203. Each of the first and second detection circuits 202 and 203 is configured to detect a target magnetic field and generate at least one detection signal.

The first detection circuit 202 is configured to detect a component in a direction parallel to the U direction of the target magnetic field and generate at least one first detection signal having a correspondence with this component. The second detection circuit 203 is configured to detect a component in a direction parallel to the V direction of the target magnetic field and generate at least one second detection signal having a correspondence with this component.

As shown in FIG. 45, the first detection circuit 202 includes four resistance portions R211, R212, R213, and R214, a power supply port V211, a ground port G211, and output ports E211 and E212. Each of the resistance portions R211 to R214 is constituted by using the magnetoresistive device 10 according to any of the first to third example embodiments. In each of the resistance portions R211 to R214, the plurality of MR elements 50 of the magnetoresistive device 10 are connected in series.

The resistance portion R211 is provided between the power supply port V211 and the output port E211. The resistance portion R212 is provided between the output port E211 and the ground port G211. The resistance portion R213 is provided between the output port E212 and the ground port G211. The resistance portion R214 is provided between the power supply port V211 and the output port E212. A voltage or current of predetermined magnitude is applied to the power supply port V211. The ground port G211 is grounded.

In FIG. 45, an arrow illustrated to overlap each of the resistance portions R211 to R214 indicates the direction of the magnetization 52m (refer to FIG. 5) of the magnetization pinned layer 52 of each MR element 50 in each of the resistance portions R211 to R214. In the example shown in FIG. 45, the direction of the magnetization 52m of the magnetization pinned layer 52 of each of the MR elements 50 in each of the resistance portions R211 and R213 is the U direction. The direction of the magnetization 52m of the magnetization pinned layer 52 of each MR element 50 in each of the resistance portions R212 and R214 is the −U direction.

As shown in FIG. 46, the second detection circuit 203 includes four resistance portions R221, R222, R223, and R224, a power supply port V221, a ground port G221, and output ports E221 and E222. Each of the resistance portions R221 to R224 is constituted by using the magnetoresistive device 10 according to any of the first to third example embodiments. In each of the resistance portions R221 to R224, the plurality of MR elements 50 of the magnetoresistive device 10 are connected in series.

The resistance portion R221 is provided between the power supply port V221 and the output port E221. The resistance portion R222 is provided between the output port E221 and the ground port G221. The resistance portion R223 is provided between the output port E222 and the ground port G221. The resistance portion R224 is provided between the power supply port V221 and the output port E222. A voltage or current of predetermined magnitude is applied to the power supply port V221. The ground port G221 is grounded.

In FIG. 46, an arrow illustrated to overlap each of the resistance portions R221 to R224 indicates the direction of the magnetization 52m (refer to FIG. 5) of the magnetization pinned layer 52 of each MR element 50 in each of the resistance portions R221 to R224. In the example shown in FIG. 46, the direction of the magnetization 52m of the magnetization pinned layer 52 of each MR element 50 in each of the resistance portions R221 and R223 is the V direction. The direction of the magnetization 52m of the magnetization pinned layer 52 of each MR element 50 in each of the resistance portions R222 and R224 is the −V direction.

A plurality of MR elements 50 of the first detection circuit 202 will be denoted by the reference sign 250A, and a plurality of MR elements 50 of the second detection circuit 203 will be denoted by the reference sign 250B, below.

The magnetic sensor 201 further includes a substrate 231 having a top surface 231a and insulating layers 232, 233, 234, 235, 236, 237, and 238. The top surface 231a of the substrate 231 is assumed to be parallel to the XY plane. The Z direction is also a direction perpendicular to the top surface 231a of the substrate 231. The top surface 231a of the substrate 231 corresponds to a “reference plane” in the technology.

The insulating layers 232, 233, and 234 are disposed on the substrate 231 in this order. The lower electrodes 61 are disposed on the insulating layer 234. The insulating layer 235 is disposed around the plurality of lower electrodes 61 on the insulating layer 234. The plurality of MR elements 250A and the plurality of MR elements 250B are disposed on the plurality of lower electrodes 61. The insulating layer 236 is disposed around the plurality of MR elements 250A and around the plurality of MR elements 250B on the plurality of lower electrodes 61 and the insulating layer 235. The plurality of upper electrodes 62 are disposed on the plurality of MR elements 250A, the plurality of MR elements 250B, and the insulating layer 236. The insulating layer 237 is disposed around the plurality of upper electrodes 62 on the insulating layer 236. The insulating layer 238 is disposed on the plurality of upper electrodes 62 and the insulating layer 237.

The magnetic sensor 201 includes a support member 240 that supports the plurality of MR elements 250A and the plurality of MR elements 250B. The support member 240 has at least one inclined surface inclined relative to the top surface 231a of the substrate 231. In the example embodiment, in particular, the support member 240 is composed of the insulating layers 232 to 234.

The support member 240 has a plurality of protruding surfaces 240c each protruding in a direction away from the top surface 231a of the substrate 231 (Z direction). Each of the plurality of protruding surfaces 240c extends in the direction parallel to the X direction. In the example shown in FIG. 48, each of the plurality of protruding surfaces 240c has a triangular roof-like overall shape formed by moving the triangular shape of the protruding surface 240c shown in FIG. 48 in a direction parallel to the X direction. The plurality of protruding surfaces 240c are arranged in the direction parallel to the Y direction at a predetermined distance from each other.

Note that the protruding surfaces 240c in the section shown in FIG. 48 may have a curved shape (arch shape). In such a case, each of the plurality of protruding surfaces 240c has a semicylindrical curved overall shape formed by moving the curved shape (arch shape) of the protruding surface 240c in the direction parallel to the X direction.

Each of the plurality of protruding surfaces 240c has an upper end farthest from the top surface 231a of the substrate 231. In the example embodiment, the upper end of each of the plurality of protruding surfaces 240c is assumed to extend in the direction parallel to the X direction. Now, focus on one protruding surface 240c of the plurality of protruding surfaces 240c. The protruding surface 240c includes a first inclined surface 240a and a second inclined surface 240b. The first inclined surface 240a refers to the area of the protruding surface 240c on the Y-direction side of the top end of the protruding surface 240c. The second inclined surface 240b refers to the area of the protruding surface 240c on the −Y-direction side of the top end of the protruding surface 240c. FIG. 47 shows the border between the first inclined surface 240a and the second inclined surface 240b in a dotted line.

The upper end of the protruding surface 240c may be the border between the first inclined surface 240a and the second inclined surface 240b. In this case, the dotted lines shown in FIG. 47 represent the upper ends of the protruding surfaces 240c.

Each of the first inclined surface 240a and the second inclined surface 240b is inclined relative to the top surface 231a of the substrate 231, i.e., the XY plane. In a section perpendicular to the top surface 231a of the substrate 231, the distance between the first inclined surface 240a and the second inclined surface 240b decreases as the distance from the top surface 231a of the substrate 231 increases.

In the example shown in FIG. 48, each of the first inclined surface 240a and the second inclined surface 240b is a flat surface. Note that, when the protruding surfaces 240c in the section shown in FIG. 48 have a curved shape (arch shape), each of the first inclined surface 240a and the second inclined surface 240b is a curved surface.

In the example embodiment, there are a plurality of protruding surfaces 240c, and thus a plurality of first inclined surfaces 240a and a plurality of second inclined surfaces 240b. The support member 240 has the plurality of first inclined surfaces 240a and the plurality of second inclined surfaces 240b.

The support member 240 further has a flat surface 240d around the plurality of protruding surfaces 240c. The flat surface 240d is a surface parallel to the top surface 231a of the substrate 231. Each of the plurality of protruding surfaces 240c protrudes from the flat surface 240d in the Z direction. In the example embodiment, the plurality of protruding surfaces 240c are arranged at a predetermined distance from each other. Thus, there exists the flat surface 240d between two protruding surfaces 240c adjacent in the direction parallel to the Y direction.

In the example embodiment, the plurality of protruding surfaces 240c and the flat surface 240d are substantially formed by the insulating layer 233. In other words, the insulating layer 233 includes a plurality of protrusions each protruding in the Z direction and a flat portion around the plurality of protrusions. Each of the plurality of protrusions extends in the direction parallel to the X direction and has a top surface with a shape corresponding to the protruding surface 240c. The plurality of protrusions are arranged in the direction parallel to the Y direction at a predetermined distance from each other. The flat portion has a substantially constant thickness (dimension in the Z direction). The insulating layer 234 has a substantially constant thickness (dimension in the Z direction) and is formed along the top surface of the insulating layer 233. The top surface of the insulating layer 234 thus forms the plurality of protruding surfaces 240c and the flat surface 240d.

Note that the insulating layer 232 has a substantially constant thickness (dimension in the Z direction) and is formed along the bottom surface of the insulating layer 233.

A plurality of lower electrodes 61 for electrically connecting the plurality of MR elements 250A are disposed on the plurality of first inclined surfaces 240a. A plurality of lower electrodes 61 for electrically connecting the plurality of MR elements 250B are disposed on the plurality of second inclined surfaces 240b. As described above, each of the first inclined surface 240a and the second inclined surface 240b is inclined relative to the top surface 231a of the substrate 231. The top surface of each of the plurality of lower electrodes 61 is thus also inclined relative to the top surface 231a of the substrate 231. The plurality of MR elements 250A and the plurality of MR elements 250B can therefore be said to be disposed on inclined surfaces inclined relative to the top surface 231a of the substrate 231. The support member 240 is a member for supporting each of the plurality of MR elements 250A and the plurality of MR elements 250B so as to be inclined relative to the top surface 231a of the substrate 231.

Next, first and second detection signals will be described with reference to FIG. 45, FIG. 46, and FIG. 48. A component in a direction parallel to the Y direction of the target magnetic field and a component in a direction parallel to the Z direction of the target magnetic field include a component in a direction parallel to the U direction and a component in a direction parallel to the V direction. When the strength of the component in a direction parallel to the U direction changes, the resistance of each of the resistance portions R211 to R214 of the first detection circuit 202 changes so that the resistances of the resistance portions R211 and R213 increase and also the resistances of the resistance portions R212 and R214 decrease, or so that the resistances of the resistance portions R211 and R213 decrease and the resistances of the resistance portions R212 and R214 increase. Consequently, the potential of each of the output ports E211 and E212 changes. The first detection circuit 202 is configured to generate a signal corresponding to the potential at the output port E211 as a first detection signal S11 and generate a signal corresponding to the potential at the output port E212 as a first detection signal S12.

When the strength of the component in a direction parallel to the V direction changes, the resistance of each of the resistance portions R221 to R224 of the second detection circuit 203 changes so that the resistances of the resistance portions R221 and R223 increase and also the resistances of the resistance portions R222 and R224 decrease, or so that the resistances of each of the resistance portions R221 and R223 decrease and the resistances of the resistance portions R222 and R224 increase. Consequently, the potential of each of the output ports E221 and E222 changes. The second detection circuit 203 is configured to generate a signal corresponding to the potential at the output port E221 as a second detection signal S21 and generate a signal corresponding to the potential at the output port E222 as a second detection signal S22.

The magnetic sensor 201 may further include a not-shown processor. The not-shown processor is configured to generate a first detection value and a second detection value, based on the first detection signals S11 and S12 and the second detection signals S21 and S22. The first detection value is a detection value corresponding to the component in a direction parallel to the Y direction of the target magnetic field. The second detection value is a detection value corresponding to the component in a direction parallel to the Z direction of the target magnetic field. The first detection value will be denoted by the sign Sy, and the second detection value will be denoted by the sign Sz, below.

The not-shown processor generates the first and second detection values Sy and Sz in the following manner, for example. The not-shown processor first generates a value S1 by an operation including obtaining a difference S11−S12 between the first detection signal S11 and the first detection signal S12, and generates a value S2 by an operation including obtaining a difference S21−S22 between the second detection signal S21 and the second detection signal S22. Then, the not-shown processor uses equations (1) and (2) below to calculate values S3 and S4.

S3=(S2+S1)/(2 cos α) (1)

S4=(S2−S1)/(2 sin α) (2)

The first detection value Sy may be the value S3 itself or may be a value obtained by adding a predetermined correction, such as gain adjustment and offset adjustment, to the value S3. Similarly, the second detection value Sz may be the value S4 itself or may be a value obtained by adding a predetermined correction, such as gain adjustment and offset adjustment, to the value S4.

The configuration, operation, and effects of the example embodiment are otherwise the same as those of any of the first to third example embodiments.

Note that the technology is not limited to the foregoing example embodiments, and various modifications can be made. For example, in the sixth example embodiment, each of the resistance portions R11 to R14 may be constituted by using the magnetoresistive device according to the fourth or fifth example embodiment. Similarly, in the seventh example embodiment, each of the resistance portions R211 to R214 and R221 to R224 may be constituted by using the magnetoresistive device according to the fourth or fifth example embodiment.

The magnetic sensor 201 according to the seventh example embodiment may include a third detection circuit configured to detect a component in a direction parallel to the X direction of the target magnetic field and generate at least one third detection signal having a correspondence with this component. The configuration of the third detection circuit may be the same as the configuration of the magnetic sensor 1 according to the first example embodiment. The target magnetic field may be terrestrial magnetism.

As described above, a magnetoresistive device according to one embodiment of the technology includes: at least one magnetoresistive element including a magnetization pinned layer having a magnetization whose direction is fixed, a free layer configured to have a magnetic vortex structure and configured so that a center of the magnetic vortex structure moves depending on a target magnetic field, and a gap layer disposed between the magnetization pinned layer and the free layer, the magnetization pinned layer, the free layer, and the gap layer being stacked together in a certain stacking direction; and at least one electrode including at least one connection portion connected to the at least one magnetoresistive element. The at least one connection portion has a contact surface being in contact with the at least one magnetoresistive element and having an identical shape to that of the free layer when seen in the stacking direction, and a circumferential surface connected to the contact surface and having a certain dimension in the stacking direction.

In the magnetoresistive device according to one embodiment of the technology, the angle of the circumferential surface with respect to the stacking direction may be within a range of 0° to 7°.

In the magnetoresistive device according to one embodiment of the technology, the at least one connection portion may have an identical shape to that of the magnetization pinned layer when seen in the stacking direction.

In the magnetoresistive device according to one embodiment of the technology, the at least one magnetoresistive element may be two magnetoresistive elements. The at least one connection portion may be a first connection portion and a second connection portion. In a section intersecting the first connection portion and the second connection portion and being parallel to the stacking direction, the circumferential surface of the first connection portion and the circumferential surface of the second connection portion may be substantially parallel to each other. The distance between the circumferential surface of the first connection portion and the circumferential surface of the second connection portion may be substantially constant irrespective of the position in the stacking direction.

In the magnetoresistive device according to one embodiment of the technology, the at least one magnetoresistive element may have a bottom surface, a top surface opposite to the bottom surface, and a side surface connecting the bottom surface and the top surface. The at least one connection portion may be connected to the top surface of the at least one magnetoresistive element.

In the magnetoresistive device according to one embodiment of the technology, the at least one magnetoresistive element may have a portion larger than that of the at least one connection portion when seen in the stacking direction.

The magnetoresistive device according to one embodiment of the technology may further include an insulating layer disposed around the at least one magnetoresistive element and the at least one connection portion. The at least one magnetoresistive element may have an end surface with which the contact surface is in contact. The insulating layer need not be in contact with the end surface. The at least one magnetoresistive element may further has a side surface to connected to the end surface. The insulating layer may have a facing surface facing the side surface of the at least one magnetoresistive element and the circumferential surface of the at least one connection portion. The angle of at least a part of the facing surface with respect to the stacking direction may be within a range of 0° to 7°.

The insulating layer may include a first portion and a second portion that are arranged to sandwich the at least one magnetoresistive element and the at least one connection portion. Each of the first portion and the second portion may include an end portion located at one end in the stacking direction. The end portion of the first portion and the end portion of the second portion may be at substantially the same position in the stacking direction. Alternatively, the end portion of the first portion and the end portion of the second portion may be at substantially different positions in the stacking direction.

The magnetoresistive device according to one embodiment of the technology may further include a yoke formed of a soft magnetic material and configured to generate, in response to application of an input magnetic field including an input magnetic field component in the stacking direction, an output magnetic field including an output magnetic field component in a direction orthogonal to the stacking direction. The at least one magnetoresistive element may be configured to detect the output magnetic field component.

The magnetoresistive device according to one embodiment of the technology may further include: a substrate having a reference plane; and a support member disposed on the substrate and having at least one inclined surface inclined relative to the reference plane. The at least one magnetoresistive element may be disposed on the at least one inclined surface.

A method for manufacturing the magnetoresistive device according to one embodiment of the technology includes: a step of forming a layered film to later become the at least one magnetoresistive element; a step of forming a hard mask on the layered film; a step of etching, by using the hard mask, the layered film to become the at least one magnetoresistive element; a step of forming an insulating layer around the at least one magnetoresistive element; a step of removing the hard mask; and a step of forming the at least one electrode.

A magnetic sensor according to one embodiment of the technology includes the magnetoresistive device according to one embodiment of the technology and is configured to detect a target magnetic field and generate a detection signal. The detection signal has a correspondence with the resistance of the at least one magnetoresistive element.

Obviously, many modifications and variations of the technology are possible in the light of the above teachings. Thus, it is to be understood that, within the scope of the appended claims and equivalents thereof, the technology may be practiced in other example embodiments than the foregoing example embodiments.

1. A magnetoresistive device comprising:
at least one magnetoresistive element including a magnetization pinned layer having a magnetization whose direction is fixed, a free layer configured to have a magnetic vortex structure and configured so that a center of the magnetic vortex structure moves depending on a target magnetic field, and a gap layer disposed between the magnetization pinned layer and the free layer, the magnetization pinned layer, the free layer, and the gap layer being stacked together in a certain stacking direction; and
at least one electrode including at least one connection portion connected to the at least one magnetoresistive element, wherein
the at least one connection portion has a contact surface being in contact with the at least one magnetoresistive element and having an identical shape to a shape of the free layer when seen in the stacking direction, and a circumferential surface connected to the contact surface and having a certain dimension in the stacking direction.

2. The magnetoresistive device according to claim 1, wherein an angle of the circumferential surface with respect to the stacking direction is within a range of 0° to 7°.

3. The magnetoresistive device according to claim 1, wherein the at least one connection portion has an identical shape to a shape of the magnetization pinned layer when seen in the stacking direction.

4. The magnetoresistive device according to claim 1, wherein:
the at least one magnetoresistive element is two magnetoresistive elements;
the at least one connection portion is a first connection portion and a second connection portion; and
in a section intersecting the first connection portion and the second connection portion and being parallel to the stacking direction, a circumferential surface of the first connection portion and a circumferential surface of the second connection portion are substantially parallel to each other.

5. The magnetoresistive device according to claim 1, wherein:
the at least one magnetoresistive element is two magnetoresistive elements;
the at least one connection portion is a first connection portion and a second connection portion; and
a distance between a circumferential surface of the first connection portion and a circumferential surface of the second connection portion are substantially constant irrespective of a position in the stacking direction.

6. The magnetoresistive device according to claim 1, wherein:
the at least one magnetoresistive element has a bottom surface, a top surface opposite to the bottom surface, and a side surface connecting the bottom surface and the top surface; and
the at least one connection portion is connected to the top surface of the at least one magnetoresistive element.

7. The magnetoresistive device according to claim 1, wherein the at least one magnetoresistive element includes a portion having a shape larger than the at least one connection portion when seen in the stacking direction.

8. The magnetoresistive device according to claim 1, further comprising an insulating layer disposed around the at least one magnetoresistive element and the at least one connection portion, wherein
the at least one magnetoresistive element has an end surface with which the contact surface is in contact,
the insulating layer is not in contact with the end surface.

9. The magnetoresistive device according to claim 8, wherein:
the at least one magnetoresistive element further has a side surface connected to the end surface;
the insulating layer has a facing surface facing the side surface of the at least one magnetoresistive element and the circumferential surface of the at least one connection portion; and
an angle of at least a part of the facing surface with respect to the stacking direction is within a range of 0° to 7°.

10. The magnetoresistive device according to claim 1, further comprising an insulating layer disposed around the at least one magnetoresistive element and the at least one connection portion, wherein
the insulating layer includes a first portion and a second portion that are arranged to sandwich the at least one magnetoresistive element and the at least one connection portion,
each of the first portion and the second portion has an end portion located at one end in the stacking direction, and
the end portion of the first portion and the end portion of the second portion are at a substantially same position in the stacking direction.

11. The magnetoresistive device according to claim 1, further comprising an insulating layer disposed around the at least one magnetoresistive element and the at least one connection portion, wherein
the insulating layer includes a first portion and a second portion that are arranged to sandwich the at least one magnetoresistive element and the at least one connection portion,
each of the first portion and the second portion has an end portion located at one end in the stacking direction, and
the end portion of the first portion and the end portion of the second portion are at different positions in the stacking direction.

12. The magnetoresistive device according to claim 1, further comprising a yoke formed of a soft magnetic material and configured to generate, in response to application of an input magnetic field including an input magnetic field component in the stacking direction, an output magnetic field including an output magnetic field component in a direction orthogonal to the stacking direction, wherein
the at least one magnetoresistive element is configured to detect the output magnetic field component.

13. The magnetoresistive device according to claim 1, further comprising:
a substrate having a reference plane; and
a support member disposed on the substrate and having at least one inclined surface inclined relative to the reference plane, wherein
the at least one magnetoresistive element is disposed on the at least one inclined surface.

14. (canceled)

14. (canceled)

15. A method for manufacturing the magnetoresistive device according to claim 1, the method comprising:
a step of forming a layered film to later be the at least one magnetoresistive element;
a step of forming a hard mask on the layered film;
a step of etching, by using the hard mask, the layered film to be the at least one magnetoresistive element;
a step of forming an insulating layer around the at least one magnetoresistive element;
a step of removing the hard mask; and
a step of forming the at least one electrode.

16. A magnetic sensor comprising the magnetoresistive device according to claim 1, the magnetic sensor being configured to detect the target magnetic field and generate a detection signal, wherein
the detection signal has a correspondence with a resistance of the at least one magnetoresistive element.
